(19) United States
(12) Patent Application Publication
(10) Pub. No.: US 2026/0033249 A1
(43) Pub. Date: Jan. 29, 2026

(54) TUNING OF SUPERCONDUCTING TUNNEL JUNCTION DEVICES USING MICROFABRICATED HEATERS

(71) Applicant: International Business Machines Corporation, Armonk, NY (US)

(72) Inventors: Jared Barney Hertzberg, Yorktown Heights, NY (US); Martin O. Sandberg, Ossining, NY (US); Eric Zhang, Sleepy Hollow, NY (US); Jason S. Orcutt, Katonah, NY (US)

(21) Appl. No.: 18/642,380

(22) Filed: Apr. 22, 2024

(51) Int. Cl. H10N 60/80; G01R 27/08; H01P 7/08; H05B 1/02; H10N 60/12

(52) U.S. Cl. CPC H10N 60/805; G01R 27/08; H01P 7/086; H05B 1/0233; H10N 60/12

(57) ABSTRACT

Techniques are provided for tuning junction resistances of superconducting tunnel junction devices (e.g., Josephson junctions) by localized thermal annealing of the superconducting tunnel junction devices. An exemplary embodiment includes a device which comprises a substrate, a quantum device comprising a superconducting tunnel junction device disposed on the substrate, and at least one heater element disposed on the substrate. The at least one heater element is configured to generate heat through resistive heating in response to a current applied to the at least one heater element, to heat a region of the substrate on which the superconducting tunnel junction device is disposed to thermally anneal the superconducting tunnel junction device.

### BACKGROUND

This disclosure relates generally to techniques for tuning junction resistances of superconducting tunnel junction devices (e.g., Josephson junctions) and, in particular, to thermal annealing techniques for tuning junction resistances of superconducting tunnel junction devices of quantum devices, e.g., Josephson junctions of superconducting quantum bits. A quantum computing system can be implemented using superconducting circuit quantum electrodynamics (cQED) architectures that are constructed using quantum circuit components such as, e.g., superconducting quantum bits (e.g., fixed-frequency transmon quantum bits), superconducting quantum interference devices (SQUIDs), and other types of superconducting devices which comprise Josephson junction devices. In particular, superconducting quantum bits (qubits) are electronic circuits which are implemented using components such as superconducting tunnel junction devices (e.g., Josephson junctions), inductors, and/or capacitors, etc., and which behave as quantum mechanical anharmonic (non-linear) oscillators with quantized states, when cooled to cryogenic temperatures. A fixed-frequency qubit, such as a transmon qubit, has a transition frequency (denoted f₀₁) which corresponds to an energy difference between a ground state |0 [symbol] and a first excited state |1 [symbol] of the qubit. It is known that the transition frequency f₀₁ of a qubit can be estimated from a normal state resistance (denoted Rₙ) of the Josephson junction of the qubit.

A solid-state quantum processor can include multiple superconducting qubits that are arranged in a given lattice structure (e.g., square lattice, heavy hexagonal lattice) to enable quantum information processing through quantum gate operations (e.g., single-qubit gate operations and multi-qubit gate operations) in which quantum information is generated and encoded in computational basis states (e.g., |0 [symbol] and |1 [symbol] ) of single qubits, superpositions of the computational basis states of single qubits, and/or entangled states of multiple qubits. Continuing technological advances in quantum processor design are enabling the rapid scaling of both the physical number of superconducting qubits and the computational capabilities of quantum processors. Indeed, while current state-of-the art quantum processors have greater than 50 qubits, it is anticipated that future quantum processors will have a much larger number of qubits, e.g., on the order of hundreds or thousands of qubits, or more.

Scaling the number of qubits (e.g., fixed frequency transmon qubits) in a qubit lattice, while maintaining high-fidelity quantum gate operations, remains a key challenge for quantum computing. For example, as superconducting quantum processors scale to larger numbers of qubits, frequency crowding within a qubit lattice becomes increasingly problematic since the transition frequencies of the qubits need to be precisely controlled to minimize gate errors that can arise from lattice frequency collisions (e.g., improper detuning between superconducting qubits can reduce the fidelity of multi-qubit gate entanglement operations). Due to semiconductor processing variabilities, however, the transition frequencies of superconducting qubits as fabricated can deviate from design targets. In this regard, it is desirable to utilize techniques for tuning qubit frequencies post-fabrication, e.g., selectively tune fixed-frequency qubits of a given qubit lattice into desired frequency patterns, to increase collision-free yield of fixed-frequency qubit lattices.

### SUMMARY

Exemplary embodiments of the disclosure include techniques for tuning junction resistances of superconducting tunnel junction devices (e.g., Josephson junctions) by localized thermal annealing of the superconducting tunnel junction devices.

For example, an exemplary embodiment includes a device which comprises a substrate, a quantum device comprising a superconducting tunnel junction device disposed on the substrate, and at least one heater element disposed on the substrate. The at least one heater element is configured to generate heat through resistive heating in response to a current applied to the at least one heater element, to heat a region of the substrate on which the superconducting tunnel junction device is disposed to thermally anneal the superconducting tunnel junction device.

Advantageously, the use of on-chip microheaters for localized thermal annealing and, thus, junction resistance tuning of superconducting tunnel junction devices (e.g., Josephson junctions of quantum bits) allows the on-chip microheaters to be disposed in close proximity to superconducting tunnel junction devices and driven with controlled currents to generate heat through resistive heating, which is sufficient for localized thermal annealing of the superconducting tunnel junction devices in a controlled manner to precisely tune the junction resistances of superconducting tunnel junction devices, post fabrication. The on-chip microheaters can be readily formed and positioned in proximity to superconducting tunnel junction devices using microfabrication techniques, and the amount of Joule heating applied to the superconducting tunnel junction devices for localized thermal annealing can be precisely known based on, e.g., the known resistance of the resistive elements of the microheaters, and the parameters (e.g., magnitude) of the controlled currents that are applied to drive the microheaters.

In another exemplary embodiment, as may be combined with the preceding paragraphs, the at least one heater element comprises at least one contact pad and a resistive element connected to the at least one contact pad, and the at least one heater element is disposed within a patterned void of a metallization feature on a surface of the substrate.

In another exemplary embodiment, as may be combined with the preceding paragraphs, the resistive element is serially connected to and between the at least one contact pad and the metallization feature.

In another exemplary embodiment, as may be combined with the preceding paragraphs, the at least one contact pad comprises a first contact pad and a second contact pad, which are disposed within the patterned void of the metallization feature, and the resistive element is serially connected to and between the first contact pad and the second contact pad.

In another exemplary embodiment, as may be combined with the preceding paragraphs, wherein the metallization feature comprises a superconducting pad of the quantum device.

In another exemplary embodiment, as may be combined with the preceding paragraphs, the metallization feature comprises a ground plane disposed on a surface of the substrate.

In another exemplary embodiment, as may be combined with the preceding paragraphs, the resistive element comprises a patterned metal trace.

In another exemplary embodiment, as may be combined with the preceding paragraphs, the resistive element comprises a doped region of the substrate.

In another exemplary embodiment, as may be combined with the preceding paragraphs, the quantum device and the at least one heater element are disposed on a same side of the substrate.

In another exemplary embodiment, as may be combined with the preceding paragraphs, the quantum device is disposed on a first side of the substrate, and the at least one heater element is disposed on a second side of the substrate and aligned to the superconducting tunnel junction device on the first side of the substrate.

In another exemplary embodiment, as may be combined with the preceding paragraphs, the at least one heater element comprises an inductive pickup coil and a resistive element connected to the inductive pickup coil, and the at least one heater element is disposed within a patterned void of a metallization feature on a surface of the substrate.

In another exemplary embodiment, as may be combined with the preceding paragraphs, the quantum device comprises a quantum bit, and the superconducting tunnel junction device is a Josephson junction of the quantum bit.

In another exemplary embodiment, as may be combined with the preceding paragraphs, the device further comprises a wiring layer which comprises wiring that is electrically connected to the at least one heater element and configured to drive the at least one heater element with an external current applied on the wiring connected to the at least one heater element.

Another exemplary embodiment includes a device which comprises a substrate, a plurality of quantum bits disposed on the substrate, each quantum bit comprising a Josephson junction, and a plurality of heater elements disposed on the substrate. Each heater element is disposed in proximity to a respective quantum bit of the plurality of quantum bits, and configured to generate heat through resistive heating in response to a current applied to the heater element, to heat a region of the substrate on which the Josephson junction of the respective quantum bit is disposed to thermally anneal the Josephson junction of the respective quantum bit.

Another exemplary embodiment includes a method which comprises contacting electrical probes to a heater element disposed on a substrate, and applying a controlled current to the heater element through the electrical probes to cause the heater element to heat a portion of the substrate through resistive heating and thermally anneal a Josephson junction of a quantum bit, which is disposed in contact with the heated portion of the substrate.

Another exemplary embodiment includes a method which comprises measuring a resistance of a Josephson junction of a quantum bit that is disposed on a substrate, and applying a controlled current to a heater element, which is disposed on the substrate in proximity to the Josephson junction of the quantum bit, to cause the heater element to generate heat through resistive heating and thereby heat a region of the substrate on which the Josephson junction is disposed to shift a resistance of the Josephson junction from the measured resistance to a target resistance.

Another exemplary embodiment includes a system which comprises a prober apparatus, and a control system operatively coupled to the prober apparatus. The control system is configured to control the prober apparatus to perform a tuning process to tune a transition frequency of at least one quantum bit of a quantum bit array on a quantum chip, wherein in performing the tuning process, the control system is configured to utilize the prober apparatus to: measure a resistance of a Josephson junction of the at least one quantum bit, and apply a controlled current to an on-chip heater element, which is disposed in proximity to the Josephson junction of the at least one quantum bit, to cause the on-chip heater element to generate heat through resistive heating and thereby heat a region of the quantum chip on which the Josephson junction is disposed to shift a resistance of the Josephson junction from the measured resistance to a target resistance.

Other embodiments will be described in the following detailed description of exemplary embodiments, which is to be read in conjunction with the accompanying figures.

### BRIEF DESCRIPTION OF THE DRAWINGS

FIG. 1 schematically illustrates a system that is configured to tune superconducting quantum devices using thermal annealing, according to an exemplary embodiment of the disclosure.

FIG. 2A schematically illustrates a quantum chip comprising integrated (on-chip) microheater elements to enable localized thermal annealing of Josephson junctions of superconducting qubits, according to an exemplary embodiment of the disclosure.

FIG. 2B schematically illustrates a quantum chip comprising on-chip microheater elements to enable localized thermal annealing of Josephson junctions of superconducting qubits, according to another exemplary embodiment of the disclosure.

FIG. 2C schematically illustrates a quantum chip comprising on-chip microheater elements to enable localized thermal annealing of Josephson junctions of superconducting qubits, according to an exemplary embodiment of the disclosure.

FIG. 3A schematically illustrates an exemplary architecture and layout of an on-chip microheater element, according to an exemplary embodiment of the disclosure.

FIG. 3B schematically illustrates an exemplary architecture and layout of an on-chip microheater element, according to another exemplary embodiment of the disclosure.

FIG. 3C schematically illustrates an exemplary architecture and layout of an on-chip microheater element, according to another exemplary embodiment of the disclosure.

FIG. 3D schematically illustrates an exemplary architecture and layout of an on-chip microheater element, according to another exemplary embodiment of the disclosure.

FIGS. 4A, 4B, and 4C schematically illustrate various metal trace patterns that can be used to implement resistive elements of on-chip microheaters, according to exemplary embodiments of the disclosure.

FIGS. 5A, 5B, and 5C are schematic views of a quantum chip comprising backside microheater elements to enable localized thermal annealing of frontside Josephson junctions of superconducting qubits, according to an exemplary embodiment of the disclosure.

FIGS. 6A and 6B are schematic views of a quantum chip comprising on-chip microheater elements to enable localized thermal annealing of Josephson junctions of superconducting qubits, and wiring to shunt the microheater elements to ground when the quantum chip is packaged, according to an exemplary embodiment of the disclosure.

FIG. 7A schematically illustrates a method for measuring a junction resistance of a Josephson junction, according to an exemplary embodiment of the disclosure.

FIG. 7B schematically illustrates a method for driving a microheater element to enable localized thermal annealing of a Josephson junction, according to an exemplary embodiment of the disclosure.

FIG. 8 illustrates a flow diagram of a calibration process for generating tuning calibration data to support localized thermal annealing of Josephson junctions using on-chip microheaters, according to an exemplary embodiment of the disclosure.

FIG. 9 illustrates a flow diagram of a process for performing trial thermal annealing operations on Josephson junctions to obtain tuning calibration data, according to an exemplary embodiment of the disclosure.

FIG. 10 illustrates a flow diagram of a process for analyzing tuning calibration data to determine tuning curves and associated calibration parameters for tuning junction resistances of Josephson junctions, according to an exemplary embodiment of the disclosure.

FIG. 11 illustrates a flow diagram of a method for tuning junction resistances of Josephson junctions, according to another exemplary embodiment of the disclosure.

FIG. 12 illustrates a flow diagram of a method for generating and updating a frequency tuning plan of a quantum bit array, according to an exemplary embodiment of the disclosure.

FIG. 13 schematically illustrates an exemplary architecture of a computing environment for implementing a control system that is configured to control a system for tuning superconducting quantum devices, according to an exemplary embodiment of the disclosure.

### DETAILED DESCRIPTION

Exemplary embodiments of the disclosure will now be described in further detail with regard to thermal annealing techniques for tuning superconducting tunnel junction devices such as Josephson junctions. The thermal annealing of superconducting tunnel junction devices is implemented using integrated (on-chip) microfabricated resistive heater elements (referred to herein as microheaters or microheater elements) that are integrally fabricated with quantum devices (e.g., superconducting qubits) on a quantum chip. The on-chip microheaters are disposed in proximity to respective superconducting tunnel junction devices (e.g., Josephson junctions) of quantum devices, and are configured to generate heat energy through resistive heating (alternatively referred to as Joule heating or Ohmic heating) when driven by controlled currents that flow through the resistive elements of the on-chip microheaters. The microheaters convert the electrical energy into heat as current flows through resistive elements of the microheaters, to thereby cause local heating of superconducting tunnel junction devices via heat conduction through a substrate of the quantum chip. The local heating of a given superconducting tunnel junction device is sufficient to thermally anneal the given superconducting tunnel junction device to shift the normal state resistance R of the given superconducting tunnel junction device. The exemplary tuning techniques as disclosed herein can be implemented to tune the junction resistances of Josephson junctions of superconducting qubits, post fabrication, to tune the transition frequencies of the superconducting qubits to target transition frequencies based on, e.g., a frequency tuning plan for superconducting qubits of a given qubit lattice and, thereby, enable frequency collision avoidance in multi-qubit lattices of a given topology (e.g., a heavy-hexagonal lattice, a square lattice, and the like).

It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. To provide spatial context to the different structural orientations of the structures shown in the drawings, XYZ Cartesian coordinates are shown in the drawings. The terms “vertical” or “vertical direction” or “vertical height” as used herein denote a Z-direction of the Cartesian coordinates shown in the drawings, and the terms “horizontal,” “horizontal direction,” “lateral,” or “lateral direction” as used herein denote an X-direction and/or a Y-direction of the Cartesian coordinates shown in the drawings.

Further, the term “exemplary” as used herein means serving as an example, instance, or illustration. Any embodiment or design described herein as “exemplary” is not to be construed as preferred or advantageous over other embodiments or designs. In addition, the terms “about” or “substantially” as used herein with regard to, e.g., percentages, ranges, etc., are meant to denote being close or approximate to, but not exactly. For example, the term “about” or “substantially” as used herein implies that a small margin of error may be present, such as 1% or less than the stated amount.

It is to be further understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

Further, the term “quantum chip” as used herein is meant to broadly refer to any device which comprises superconducting quantum devices including, e.g., superconducting qubits and other types of quantum devices which implement superconducting tunnel junction devices (e.g., Josephson junctions). For example, a quantum chip can comprise a semiconductor die onto which is formed an array (lattice) of qubits, which is fabricated on a wafer comprising multiple dies, and which can be diced (cut) from the wafer using a die singulation process to provide a singulated die. In some instances, a quantum chip can be a wafer with multiple dies. In the context of quantum computing, a quantum chip may comprise one or more processors for a quantum computer.

As is known in the art, a Josephson junction is a nonlinear element which is based on a dissipation-less tunneling of Cooper pairs between two superconducting elements that are coupled by a weak link (e.g., a thin insulating barrier). The Josephson effect produces a current (referred to as a supercurrent), that flows continuously without dissipation through the Josephson junction, and without a voltage applied across the Josephson junction. In particular, a Josephson junction is a nonlinear device which has a nonlinear Josephson inductance L_{J} that is determined as:

$${L}_{J} = \frac{{Φ}_{0}}{2 π {I}_{c} cos φ} ,$$

where I_{c} denotes a critical current of the Josephson junction, where Φ₀ denotes the magnetic flux quantum,

$${Φ}_{0} = \frac{h}{2 e} ,$$

and where φ denotes a superconducting phase difference across the Josephson junction, i.e., φ=φ₁−φ₂. The Josephson inductance L_{J} is non-linear with respect to φ. As is known in the art, the magnetic flux quantum Φ₀ is a fundamental unit of superconducting magnetic flux which represents a quantization of magnetic flux threading a superconducting loop, wherein Φ₀=h/(2e)≈2.07×10⁻¹⁵ Weber (volt-seconds), where h is the Planck constant, and where e denotes a magnitude of electron charge.

Further, the junction critical current I_{c} denotes a maximum amount of current that can coherently tunnel through the junction while exhibiting no dissipation, where the junction critical current is determined by

$${I}_{c} = \frac{2 e {E}_{J}}{ℏ}$$

The junction critical current I_{c} is a function of a Josephson energy E_{J} of the Josephson junction, wherein

$${E}_{J} = {L}_{J 0} {I}_{C}^{2} ,$$

wherein L_{J0} denotes the maximum Josephson inductance of the Josephson junction. For currents smaller than the critical current I_{c}, the Josephson junction behaves as a nonlinear inductor. Furthermore, with a Josephson junction, a resulting superconducting current I which flows through the tunnel junction, and junction voltage V across the tunnel junction, are related to the superconducting phase difference φ=φ₁−φ₂ as follows: I=I_{c} sin φ, and

$$V = \frac{{Φ}_{0} d φ}{2 π dt} .$$

Typically, superconducting qubits are implemented using at least one Josephson junction that is shunted by a superconducting capacitor. The Josephson junction functions as a nonlinear inductor which, when shunted with a capacitor, forms an anharmonic LC oscillator with individually addressable energy levels. For example, a transmon qubit is a type of superconducting qubit which comprises a Josephson junction that is shunted by a capacitor to form an anharmonic LC oscillator in which the two lowest energy level corresponding to the ground state |0 [symbol] and the first excited state |1 [symbol] are utilized as the computational basis for encoding quantum data. A superconducting transmon qubit has a transition frequency f₀₁ (or eigen frequency) which is determined based on the Josephson energy E_{J} and a charging energy E_{C} of the transmon qubit.

In particular, the transition frequency f₀₁ of a superconducting transmon qubit is determined as ωh=8E_{J}E_{C}−E_{C}, where ω=2πf₀₁, and where

$$ℏ = \frac{h}{2 π} .$$

The charging energy E_{C} is inversely proportional to a total capacitance C of the superconducting transmson qubit, wherein the charging energy is determined as

$${E}_{C} = \frac{{e}^{2}}{2 C} .$$

The Josephson energy E_{J} is proportional to the critical current, and is determined as

$${E}_{J} = {I}_{c} \frac{ℏ}{2 e} = \frac{πΔ}{2 e {R}_{n}} \cdot \frac{ℏ}{2 e} ,$$

where Δ denotes a superconducting gap, and where Rₙ denotes the “normal state” junction resistance of the Josephson junction of the transmon qubit when the metal of the qubit is not superconducting. For instance, when measured at room temperature, the junction exhibits a “normal state” resistance. These equations illustrate that the transition frequency f₀₁ of a transmon qubit can be varied by varying the total capacitance C of the transmon qubit and/or the normal state junction resistance Rₙ of the Josephson junction of the transmon qubit.

A standard process for fabricating superconducting tunnel junction devices, such as Josephson junctions for superconducting qubits, is based on scanning electron-beam lithography and double-angle shadow evaporation techniques which utilize shadow evaporation masks to fabricate overlapping electrodes of a superconducting tunnel junction device, with an intermediate in-situ oxidation to form a junction barrier between the overlapping electrodes. Such techniques can be used to fabricate Josephson junctions having either Dolan or Manhattan patterns, as is known in the art. In some embodiments, the overlapping electrodes of the Josephson junctions are fabricated using evaporated aluminum (Al), where an in-situ oxidation is performed after a first angle evaporation process to form an aluminum oxide (AlOx) layer on surfaces of the aluminum electrodes that are formed as a result of the first angle evaporation process. The double-angle shadow aluminum evaporation process results in the formation of Josephson junctions each comprising a three-layer stack of Al/AlOx/Al where the tunneling occurs across the aluminum oxide tunnel barrier layer.

The primary variables that affect the normal state junction resistance Rₙ, and therefore the Josephson energy of Josephson junctions, are the overlap area between the two junction electrodes and the thickness of the tunnel barrier layer therebetween. For example, the critical current of a Josephson junction will be determined by the overlap area of the first and second electrodes (e.g., Al electrodes) of the Josephson junction and the thickness of the tunnel barrier layer (e.g., AlOx) between the first and second electrodes. Even when prepared using high-resolution e-beam lithography, the spread in resistance among junctions on a given chip is at best on the order 2%. Some of this resistance spread could be result of the microscopic structure of the barrier where tunneling depends exponentially on the thickness of the tunnel barrier layer. It has been suggested that as little as 10% of the area of the Josephson junction may contribute to the tunneling current due to the nonuniform thickness of the tunnel barrier layer. Therefore, it is highly desirable to implement techniques for tuning the junction resistance of the Josephson junctions, post fabrication, to thereby reduce the resistance spread, and hence also reduce the frequency spread of qubits.

Indeed, the ability to tune the frequency of superconducting qubits (e.g., transmon qubits) to a high degree of accuracy, post fabrication, is important for scaling the number of qubits for quantum processing. For example, in a relatively large qubit lattice, if the transition frequencies of the qubits are not well-controlled, frequency collisions in the qubit lattice can easily arise. Frequency collisions are conditions where the alignment of qubit frequencies causes unwanted interaction and gate degradation. For a typical quantum device that implements cross resonance (CR) gates, there are at least 7 types of frequency collisions that may arise between pairs of qubits lying at nearest neighbor or next-nearest-neighbor sites in the lattice.

It is known that thermal annealing of superconducting tunnel junction devices (e.g., Josephson junctions) can be utilized to change the normal state junction resistance Rₙ, post fabrication. For example, laser annealing techniques utilize laser energy to enable localized thermal annealing of Josephson junctions of qubits to thereby adjust and stabilize the junction resistance Rₙ of the Josephson junctions and thereby tune respective qubit transition frequencies for) with high precision. In particular, laser tuning techniques such as Laser Annealing of Stochastically Impaired Qubits (LASIQ) are utilized to tune the transition frequencies of superconducting qubits, post fabrication, by laser tuning junction resistances of the qubit Josephson junctions, and thereby selectively tune fixed-frequency qubits of a given qubit lattice into desired frequency pattern to increase collision-free yield of fixed-frequency qubit lattices.

The tuning of qubit transition frequencies through laser annealing, however, is non-trivial due to, e.g., inherent variabilities of the laser anneal process itself and/or the equipment that is utilized to perform such laser annealing, post fabrication, to tune the qubit transition frequencies in a given qubit lattice. Moreover, laser tuning does not allow measurement of junction resistances as the Josephson junctions are being laser tuned due to the presence of optically activated carriers. Moreover, laser tuning techniques require separate optical alignment operations including a first optical alignment process to optically align electrical probes to a given Josephson junction to measure the junction resistance, and a second optical alignment process to align a laser beam illumination pattern (e.g., one or more laser beam spots) with the Josephson junction before the laser thermal anneal operation. In this regard, the need for multiple optical alignment operations limits the throughput of the overall laser tuning process.

As noted above, exemplary embodiments of the disclosure provide systems and methods for utilizing on-chip microheaters that are disposed in proximity to superconducting tunnel junction devices (e.g., Josephson junctions), which are driven by controlled currents to cause localized heating of the superconducting tunnel junction devices and thereby thermally anneal the superconducting tunnel junction devices to shift their respective normal state junction resistances. As explained in further detail below, as compared to laser tuning techniques, the use of on-chip microheater elements to enable thermal annealing of superconducting tunnel junction devices provides various advantages. For example, the exemplary thermal annealing techniques disclosed herein do not require a separate optical alignment for laser annealing. In addition, a same prober system for measuring the junction resistances of the Josephson junctions is utilized to apply the controlled currents to the on-chip microheater elements to cause localized heating, and thus thermal annealing, of the Josephson junctions.

For illustrative purposes, the exemplary embodiments will be described in the context of tuning junction resistances of Josephson junctions and, in particular, tuning the junction resistances of Josephson junctions of superconducting qubits (e.g., transmon qubits) for the purpose of tuning the transition frequencies of the superconducting qubits. It is to be understood, however, that the exemplary current tuning techniques can be implemented to tune the junction resistances of superconducting tunnel junction devices (e.g., Josephson junctions) that are implemented in other types of quantum devices including, but not limited to, superconducting quantum interference devices (SQUIDs), flux-tunable qubit couplers, parametric modulator circuits, parametric amplifier circuits, Josephson junction ring modulators, and other types of superconducting devices which comprise Josephson junction devices.

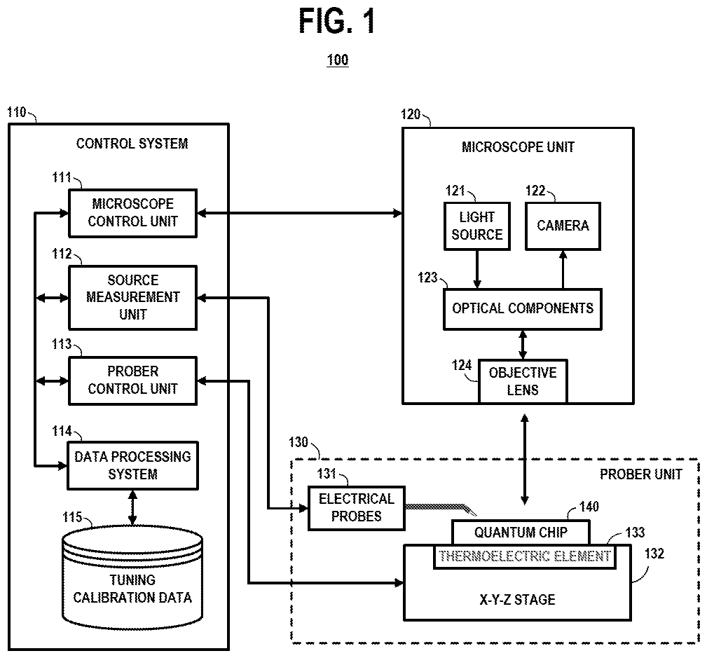

For example, FIG. 1 schematically illustrates a system that is configured to tune superconducting quantum devices by thermal annealing, according to an exemplary embodiment of the disclosure. In particular, FIG. 1 schematically illustrates a system 100 that is configured for tuning the junction resistances of superconducting tunnel junction devices (e.g., Josephson junctions), post fabrication, using a prober apparatus that is configured to perform junction resistance measurements, as well as generate controlled currents to drive on-chip microheater elements on a quantum chip to cause local resistive heating (localized thermal annealing) of Josephson junctions on the quantum chips to shift the junction resistances of the Josephson junctions.

As schematically shown in FIG. 1, the system 100 comprises a control system 110, a microscope unit 120, and a prober unit 130 (or prober apparatus 130). The control system 110 comprises a microscope control unit 111, a source measurement unit (SMU) 112, a prober control unit 113, a data processing system 114, and a database of tuning calibration data 115. The microscope unit 120 comprises a light source 121, a camera 122, a plurality of optical components 123, and an objective lens 124. The prober unit 130 comprises electrical probes 131 (e.g., a probe card), and an X-Y-Z stage 132 having a wafer chuck which comprises a thermoelectric element 133. A quantum chip 140 (or any other similar device under test) can be mounted to the X-Y-Z stage 132. In some embodiments, the quantum chip 140 comprises a lattice of superconducting qubits and on-chip microheater elements that are disposed in proximity to Josephson junctions of the superconducting qubits, where the Josephson junctions can be thermally annealed using localized heating which results from driving the on-chip microheater elements with controlled currents that are generated by the SMU 112 and applied to the on-chip microheater elements through the electrical probes 131 using the prober unit 130 under the control of the prober control unit 113. The localized heating of a given Josephson junction shifts the normal state junction resistance of the given Josephson junctions and, thus, tunes the transition frequency f₀₁ of a corresponding superconducting qubit, post-fabrication.

The microscope unit 120 implements the light source 121 and the camera 122 for illuminating and viewing target features (e.g., qubits and corresponding Josephson junctions) on the surface of the quantum chip 140 within a given field of view (FOV) of the microscope unit 120. In some embodiments, the light source 121 comprises any suitable light generating device including one or more light emitting diodes (LEDs) with desired photonic wavelengths, a monochromatic light source, etc. The light source 121 together with some of the optical components 123 in the optical viewing path implement Kohler illumination to create uniform illumination of the target features in the FOV of the microscope unit 120 and to ensure that an image of the light source 121 is not visible in the resulting images captured by the camera 122.

In some embodiments, the camera 122 comprises a charge-coupled device (CCD) image sensor, or an infrared (IR) complementary metal oxide semiconductor (CMOS) image sensor. The camera 122 is utilized to capture images of a target region on the surface of the quantum chip 140 to facilitate, e.g., aligning the electrical probes 131 to contact electrodes to perform junction resistance measurement and thermal annealing tuning operations. For example, in some embodiments, the Josephson junction of a given qubit is aligned to the center of the FOV of the microscope unit 120 using pattern recognition based on, e.g., a Josephson junction template image. The optical components 123 include various types of optical components for directing, reflecting, focusing, modifying, and shaping, etc., the optical signals (e.g., visible light/IR light for viewing) as needed for the given application. For example, the optical components 123 include components such as mirrors, beam splitters, filters, and various lenses such as a tube lens, an objective lens, relay lenses, etc. The objective lens 124 is the lens that is located closest to the device under test (quantum chip 140) and serves to provide the base magnification for generating a magnified image that is viewed by the camera 122.

As schematically shown in FIG. 1, the quantum chip 140 is mounted to the automated X-Y-Z stage 132 of the prober unit 130, which is controllably moved in three dimensions (under control of the prober control unit 113) to align target devices of the quantum chip 140 within the FOV of the microscope unit 120. The alignment allows the electrical probes 131 (e.g., a set of microscopic contacts or probes of the probe card) to be aligned with contact pads on the surface of the quantum chip 140 to thereby enable (i) contact between the electrical probes 131 and contact pads (e.g., capacitor pads) of Josephson junctions on the quantum chip 140 to perform junction resistance measurements, and (ii) contact between the electrical probes 131 and contact pads of the on-chip microheater elements on the quantum chip 140 to apply controlled currents to the on-chip microheater elements to cause localized heating of Josephson junction to tune the respective junction resistance of the Josephson junctions.

For example, in some embodiments, the prober control unit 113 utilizes pattern recognition techniques to automatically align the electrical probes 131 with contact pads on the surface of the quantum chip 140. More specifically, in some embodiments, the prober control unit 113 operates in conjunction with the microscope control unit 111 to utilize the microscope unit 120 as pattern recognition optics to identify the positions of contact pads on the surface of the quantum chip 140 relative to the tips of the electrical probes 131. The alignment ensures precise registration between the contact pads and the tips of the electrical probes 131. To facilitate the alignment, an automated pattern recognition process is performed in which features of an image captured by the camera 122 are automatically aligned to corresponding features of a template image to ensure proper positioning of target contact pads of Josephson junctions and/or target contact pads of on-chip microheater elements and, thereby, ensure accurate registration between the contact pads and the electrical probes 131 to perform junction resistance measurements and/or apply controlled currents to on-chip microheater elements to local thermally anneal Josephson junctions.

In some embodiments, the electrical probes 131 are implemented using a probe card which comprises (i) probe pairs that are arranged and configured to land on contact pads (e.g., capacitor pads) of Josephson junctions to perform a 4-wire resistance measurement (or Kelvin resistance measurement) to measure the normal state junction resistances of Josephson junctions and (ii) probe pairs that are arranged and configured to land on contact pads of microheater elements to apply controlled currents to the microheater elements to perform localized thermal annealing of Josephson junctions. In general, a 4-wire (Kelvin) resistance measurement involves determining the resistance of a given Josephson junction by measuring a current (I) flow through the junction as well as a voltage (V) drop across the junction, and determining the junction resistance R_{J} from Ohm's Law, i.e., R_{J}=V/I.

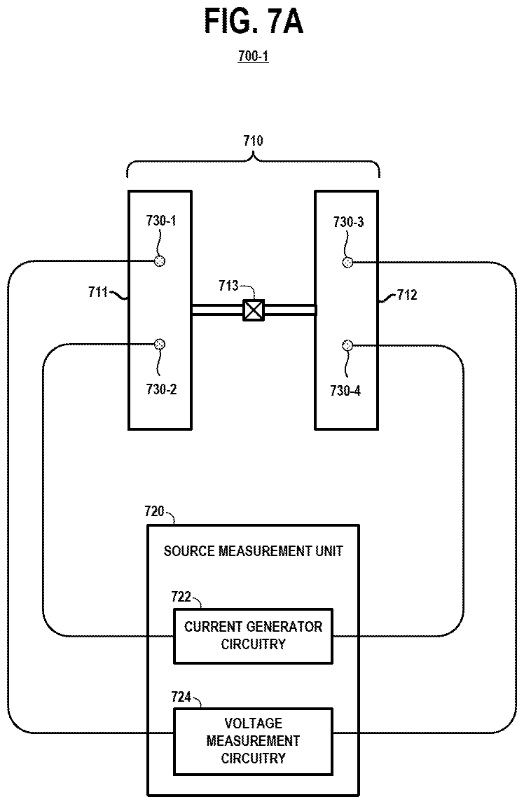

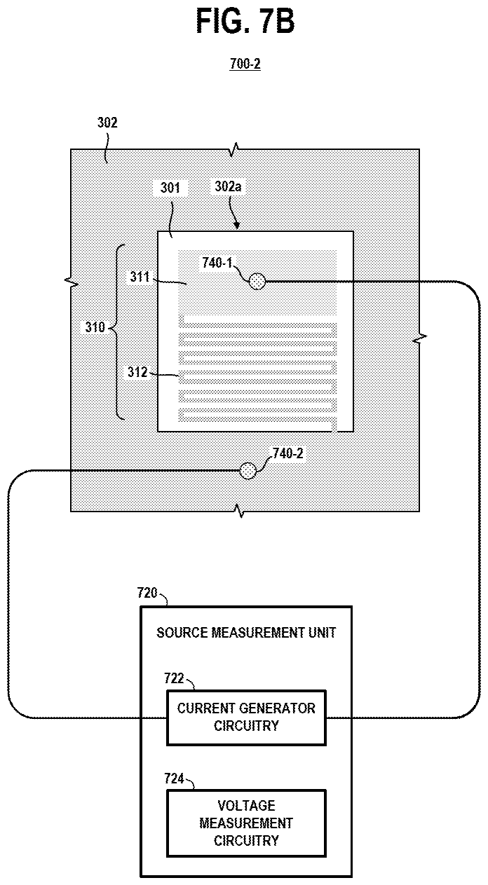

In addition, the electrical probes 131 are utilized for applying controlled currents to on-chip microheater elements to perform localized heating and, thus, localized thermal annealing of Josephson junctions to tune the junction resistances of respective Josephson junctions. The SMU 112 comprises a test instrument which combines a sourcing function (to precisely source voltage and current pulses/signals) and a measurement function (measure voltage or current) on the same group of probes. In this regard, the SMU 112 is configured to generate and measure voltage and/or currents on the electrical probes 131 that are designated to perform junction resistance measurements, as well as generate and apply controlled currents on the electrical probes 131 that are designated to facilitate thermal annealing operations, as discussed herein. Exemplary embodiments for utilizing the electrical probes 131 and SMU 112 to perform 4-wire (Kelvin) resistance measurement operations, and apply controlled currents to on-chip microheater elements, will be discussed in further detail below in conjunction with, e.g., FIGS. 7A and 7B.

In some embodiments, the electrical probes 131 comprise a probe card that is mechanically mounted in a fixed position to the prober unit 130. In some embodiments, an integration of the microscope unit 120 and the prober unit 130 is configured to ensure that a probing plane is displaced from a sample imaging plane by a preset amount, e.g., 70 microns, 80 microns, etc. In this configuration, the electrical probes 131 (probe card) are fixedly displaced from the image plane, and the Z-position of the X-Y-Z stage 132 (with the quantum chip 140 mounted thereon) is moved into a default contact position to make electrical contact between the electrical probes 131 and target contact pads on the quantum chip 140, under control of the prober control unit 113.

In some embodiments, the thermoelectric element 133 is utilized as a thermal control system (e.g., temperature-controlled wafer chuck system, or other suitable types of heating/cooling systems) that is configured to (i) heat the quantum chip 140 to perform a bulk thermal anneal operation for shifting the junction resistances of the Josephson junctions of the quantum chip 140, and (ii) cool the quantum chip 140 to desired temperature to perform junction resistance measurements and junction resistance tuning operations. In this regard, the X-Y-Z stage 132 may be temperature controlled to allow high-temperature anneals (e.g., bulk anneals) or low-temperature probing for low-noise electrical resistance measurements. For example, in some embodiments, the temperature-controlled wafer chuck system can be temperature controlled (via the thermoelectric element 133) in a range of −60° C. to 300° C.

As noted above, in some embodiments, various functions of the microscope unit 120, and the prober unit 130 are automatically controlled by the control system 110. In some embodiments, the microscope control unit 111, the SMU 112, and the prober control unit 113 comprise respective hardware interfaces for interfacing with the microscope unit 120 and the prober unit 130, as needed, to generate and apply control signals to control various components of such units 120 and 130, and to receive and process signals (e.g., image data, electrical measurements, feedback controls signals, etc.) received from components of such units 120 and 130. The data processing system 114 comprises one or more processors that execute software programs/routines to control operations of the microscope unit 120 and the prober unit 130 by processing data received from the microscope control unit 111, the SMU 112, and the prober control unit 113 (e.g., to perform automated pattern recognition for active alignments, perform junction resistance measurements, junction resistance tuning computations, etc.), and generating and outputting control signals to cause the microscope control unit 111, the SMU 112, and the prober control unit 113 to control the operations of the microscope unit 120 and the prober unit 130 in a coordinated manner, when performing junction resistance measurements and junction resistance tuning operations, as discussed herein.

For example, in some embodiments, the microscope control unit 111 is configured to control the operation of the light source 121, the camera 122, and one or more of the optical components 123 (e.g., tube lens) that make up the image path of the microscope unit 120. The microscope control unit 111 can generate control signals to cause the camera 122 to capture images within the FOV of the microscope unit 120 and send images to the microscope control unit 111. The microscope control unit 111 can be configured to preprocess the image data into a suitable format for processing by the data processing system 114 to perform automated pattern recognition functions to perform electrical probe alignment operations as discussed herein.

Moreover, the SMU 112 and the prober control unit 113 are configured to control operations of the prober unit 130. For example, the SMU 112 comprises hardware (e.g., current and voltage generation and measurement circuitry) for generating currents that are applied to designated probes of the electrical probes 131 to perform junction resistance measurements, e.g., 4-wire (Kelvin) resistance measurements, and for generating controlled currents (e.g., DC current pulses or AC current pulses) that are applied to designed probes of the electrical probes 131 to drive the on-chip microheater elements to perform localized thermal annealing of Josephson junctions for tuning the Josephson junctions. In some embodiments, the current and/or voltage measurements of the SMU 112 can be digitized and sent to the data processing system 114 for computing junction resistances and performing other computations, as needed, to perform junction resistance measurements and tuning functions as discussed herein. In addition, the prober control unit 113 comprises control circuitry and an interface, which are configured to generate and apply control signals to the prober unit 130 to control the operation of motors or actuators of the X-Y-Z stage 132 to precisely control movement and positioning of the X-Y-Z stage 132.

In some embodiments, the data processing system 114 executes a tuning calibration process to perform tuning calibration operations on test quantum circuits having quantum devices (e.g., superconducting qubits) with test Josephson junctions and test microheater elements which are disposed in proximity to the test Josephson junctions, wherein the tuning calibration operations are performed by driving the test microheater elements, which are associated with groups of test Josephson junctions, with controlled currents having different (unique) combinations of controlled current parameters (e.g., different magnitudes, durations, sequences, frequencies, etc.). The tuning calibration operations generate tuning calibration data which represents the tuning characteristics of test Josephson junction that are thermally annealed with different thermal profiles resulting from the local resistive heating of the test microheater elements being driving with different controlled currents. The tuning calibration data is persistently stored in the database of tuning calibration data 115, wherein such tuning calibration data can be subsequently accessed and utilized to configure controlled currents for driving on-chip microheater elements for junction resistance tuning of Josephson junctions by thermal annealing.

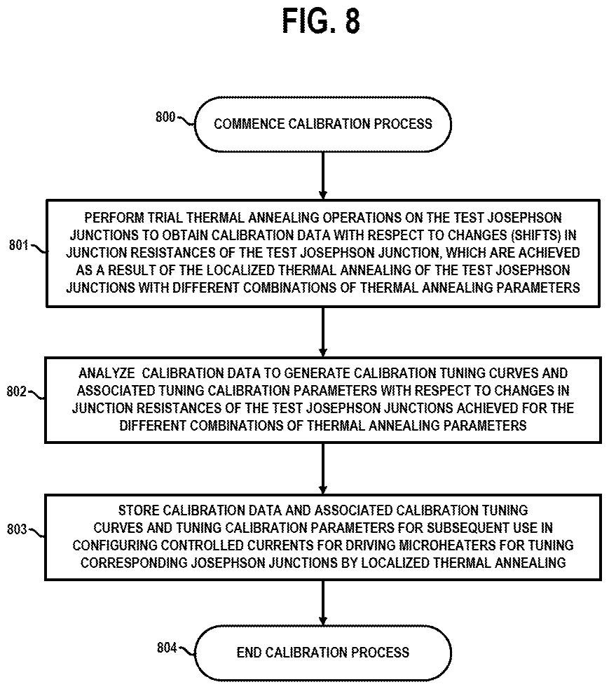

As explained in further detail below in conjunction with FIGS. 8, 9, and 10, the tuning calibration operations can be performed by partitioning the test Josephson junctions and associated microheater elements into test groups, wherein each test group comprises a group of test Josephson junctions and associated microheater elements. For each test group, the associated microheater elements are driven using a controlled current having a unique combination of controlled current parameters (e.g., pulse magnitude, pulse duration, etc.) to cause localized thermal annealing of the test Josephson junctions, which shifts the junction resistances of the test Josephson junctions. The resulting junction resistance shifts of the test Josephson junctions of all test groups are measured and analyzed to generate tuning calibration data, which is indicative of the tuning characteristics of the test Josephson by driving the associated microheaters with different controlled currents. The calibration data can be subsequently utilized to tune actual Josephson junctions, which correspond to the test Josephson junctions, by configuring controlled currents for driving associated on-chip microheaters, to tune the actual Josephson junctions via thermal annealing.

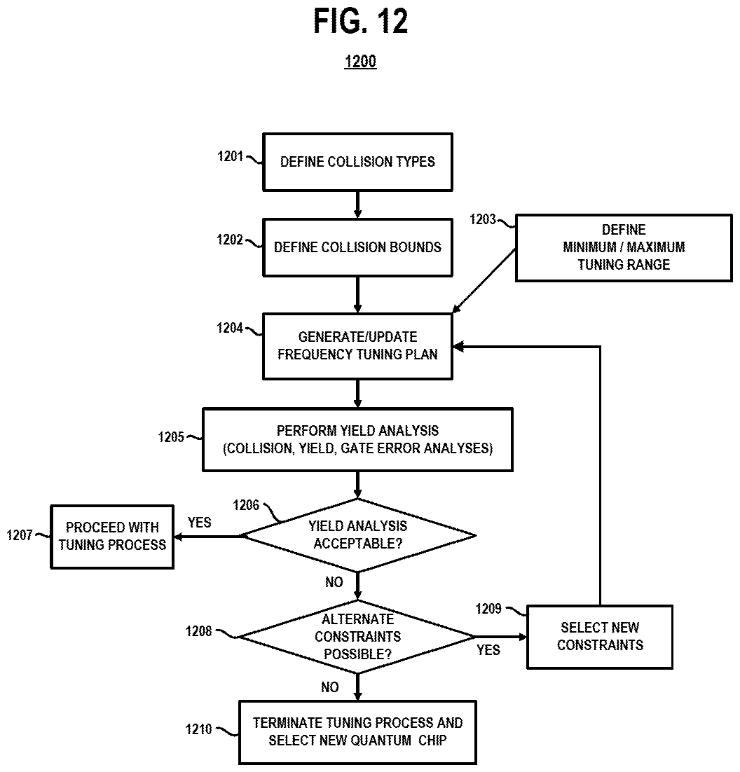

In some exemplary embodiments, the control system 110 may be implemented using any suitable computing system architecture which is configured to implement methods to support the automated control processes as described herein by executing computer readable program instructions that are embodied on a computer program product which includes a computer readable storage medium (or media) having such computer readable program instructions thereon for causing a processor to perform control methods as discussed herein. An exemplary architecture of a computing environment for implementing a control system that is configured to control junction resistance measurement operation and junction resistance tuning operations, will be discussed in further detail below in conjunction with FIG. 12.

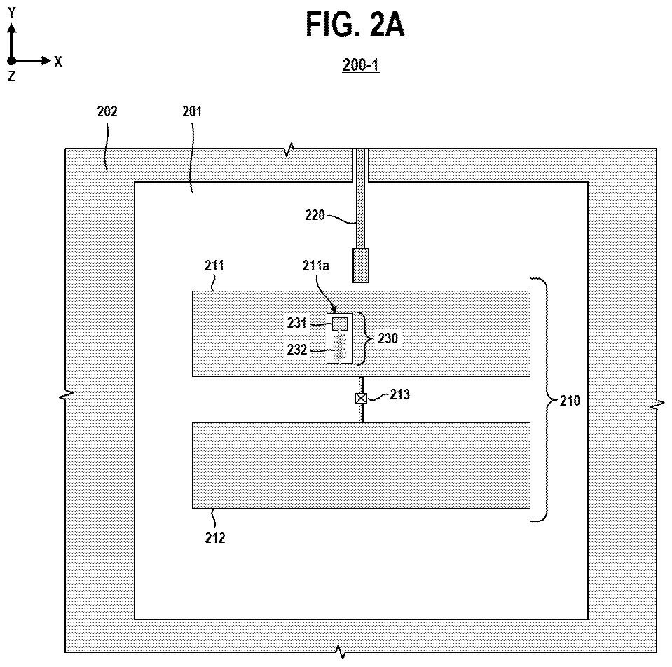

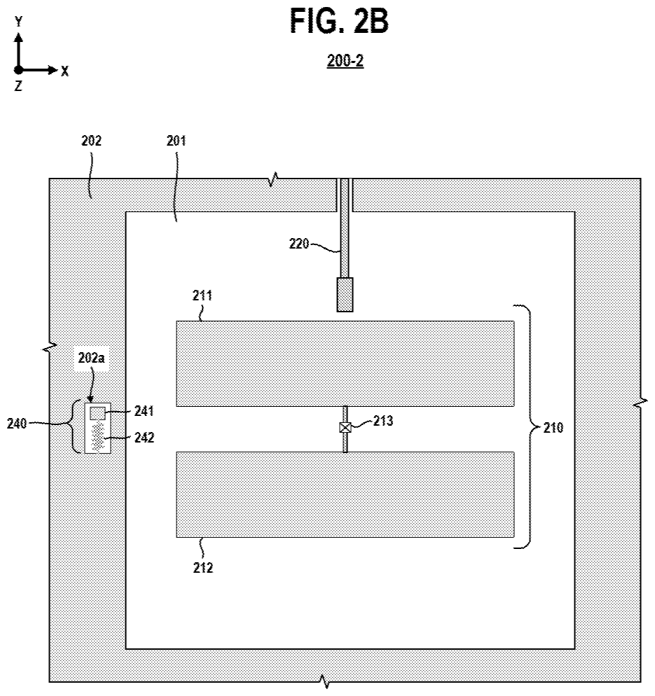

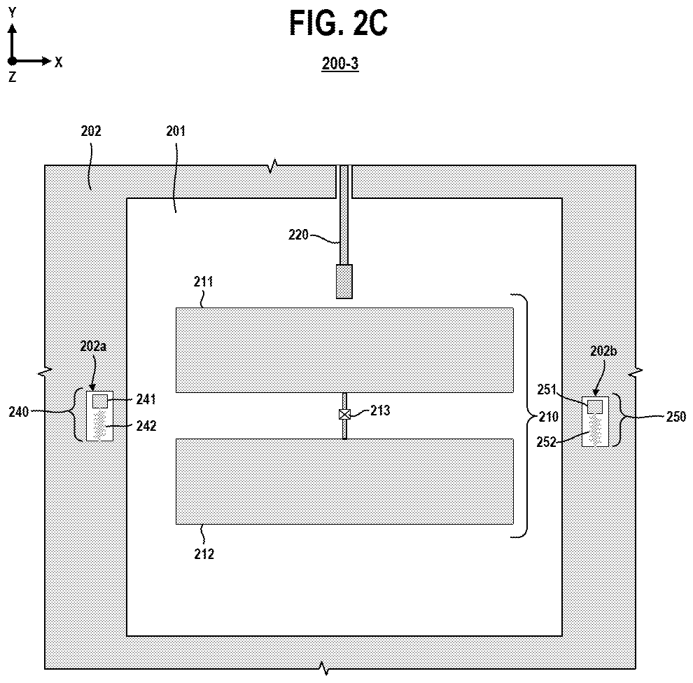

Various techniques for integrating quantum devices (e.g., superconducting qubits) with associated microheater elements on a quantum chip to facilitate localized thermal annealing of Josephson junctions, post fabrication, will now be discussed in further detail in conjunction with FIGS. 2A, 2B, and 2C. For purposes of illustration, the exemplary embodiments will be discussed in the context of superconducting qubits and integrating one or more on-chip microheater elements within and/or in close proximity to the Josephson junction(s) of a given superconducting qubit to facilitate the localized thermal annealing of the Josephson junction(s) of a given superconducting qubit.

For example, FIG. 2A schematically illustrates a quantum chip comprising on-chip microheater elements to enable localized thermal annealing of Josephson junctions of superconducting qubits, according to an exemplary embodiment of the disclosure. In particular, FIG. 2A is schematic top plan view of a quantum chip 200-1 which comprises a substrate 201, and a plurality of patterned features disposed on a frontside surface of the substrate 201. For example, the patterned features comprise a ground plane 202, a superconducting qubit 210, qubit readout resonator 220, and a microheater element 230 (or microheater 230). The superconducting qubit 210 comprises a first superconducting pad 211, a second superconducting pad 212 (alternatively, superconducting capacitor pads), and a Josephson junction 213 coupled to, and disposed between, the first and second superconducting pads 211 and 212. The superconducting qubit 210 comprises a transmon qubit which comprises a superconducting capacitor structure connected in parallel with a Josephson junction, wherein the first and second superconducting pads 211 and 212 comprise capacitor electrodes of a coplanar capacitor structure of the superconducting qubit 210. The Josephson junction 213 functions as a non-linear inductor which, when shunted with the capacitor formed by the first and second superconducting pads 211 and 212, forms an anharmonic LC oscillator with individually addressable energy levels of computational basis states (e.g., two lowest energy level corresponding to the ground state |0 [symbol] and the first excited state |1 [symbol] ) and a given transition frequency f₀₁.

In an exemplary embodiment, the ground plane 202, the qubit readout resonator 220, and the first and second superconducting pads 211 and 212 of the superconducting qubit 210 are photolithographically patterned from a layer superconducting metal (or metallic material) such as aluminum (Al), niobium (Nb), tantalum (Ta), titanium (Ti), tungsten (W), tin (Sn), molybdenum (Mo), or nitrides of the same, or combinations thereof, and/or the like. A superconducting metal or metallic material exhibits superconducting properties (e.g., no electrical resistance, expels magnetic fields when in a superconducting state) at or below a superconducting critical temperature. The Josephson junction 213 comprises first and second electrodes, and a junction barrier layer (e.g., oxide layer) disposed between overlapping portions of the first and second electrodes. The Josephson junction 213 is fabricated using known techniques such as scanning electron-beam lithography and double-angle shadow evaporation techniques which utilize shadow evaporation masks to fabricate overlapping electrodes of tunnel junction devices, with an intermediate in-situ oxidation to form a junction barrier between the overlapping electrodes, or other state of the art techniques.

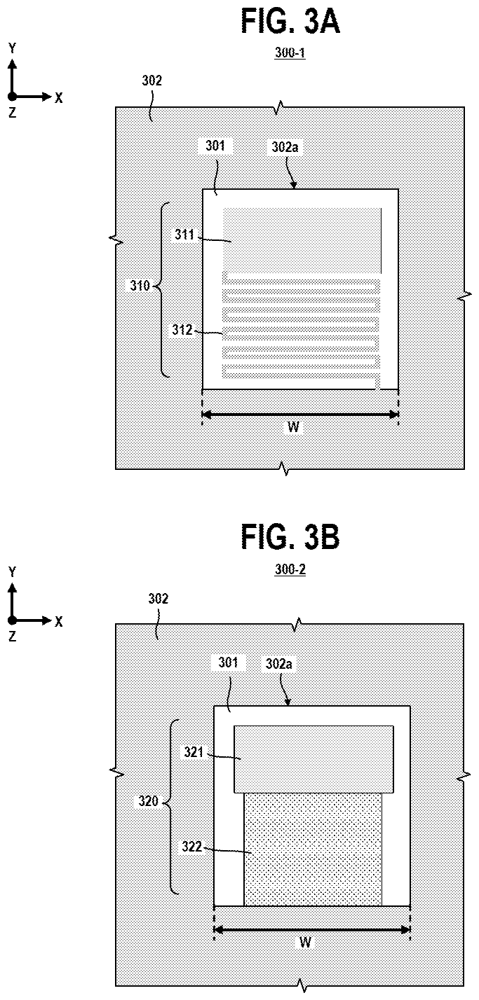

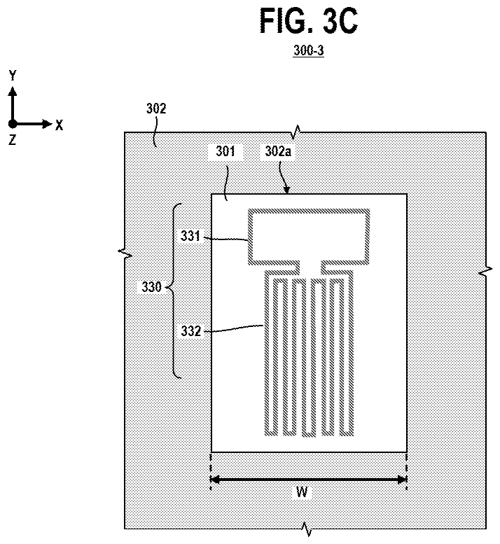

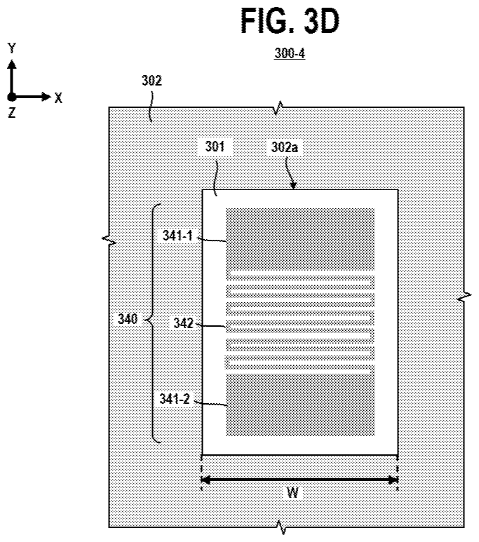

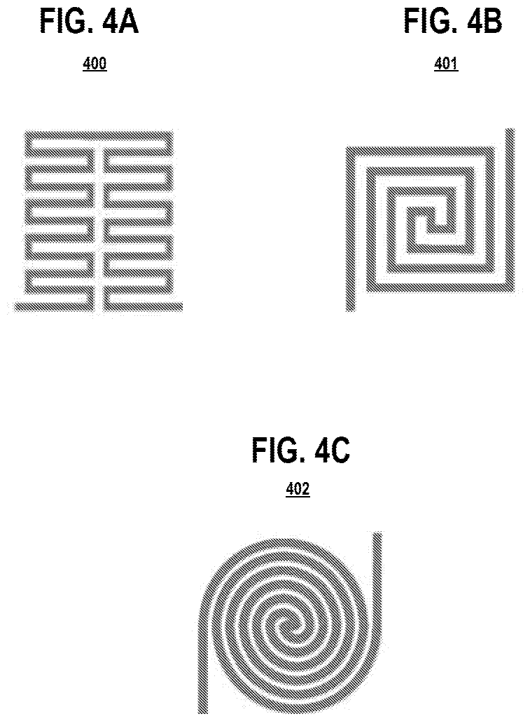

FIG. 2A illustrates an exemplary embodiment in which the microheater 230 is disposed within a void region 211a of the first superconducting pad 211 to be located in relatively close proximity to the Josephson junction 213. The microheater 230 comprises a contact pad 231 and a resistive element 232. The resistive element 232 is series connected between the contact pad 231 and the first superconducting pad 211 of the superconducting qubit 210. For case of illustration, the resistive element 232 is shown in FIG. 2A as a schematic symbol of a resistor. However, the resistive element 232 can be implemented using various resistive structures, exemplary embodiments of which will be explained in further detail below in conjunction with FIGS. 3A and 3B. In some embodiments, the contact pad 231 and the resistive element 232 of the microheater 230 are photolithographically patterned from the same layer of superconducting metal (e.g., niobium) that is patterned to form, e.g., the ground plane 202, the qubit readout resonator 220, and the first and second superconducting pads 211 and 212 of the superconducting qubit 210.

In an exemplary embodiment, the microheater 230 is driven by a controlled current which is applied to the microheater 230 through a pair of electrical probes, wherein a first electrical probe tip is contacted to the contact pad 231 of the microheater 230 and a second electrical probe tip is contacted to the first superconducting pad 211 of the superconducting qubit 210. The controlled current flows through the resistive element 232 to cause the resistive element 232 to generate heat through resistive heating (joule heating) which, in turn, causes a localized heating of the region of the substrate 201 surrounding the microheater 230 through conductive heat transfer. The localized heating of the substrate 201 results in the localized thermal annealing of the Josephson junction 213 to shift the junction resistance of the Josephson junction 213. In this configuration, the localized thermal annealing of the Josephson junction 213 can be performed by driving the microheater 230 with a controlled current, without heating the Josephson junctions of neighboring superconducting qubits.

In the exemplary embodiment of FIG. 2A, the microheater 230 is positioned and designed so that the microheater 230 has no adverse effect on the operation of the superconducting qubit 210 when the quantum chip 200-1 is cooled to cryogenic temperatures. For example, even with microheater 230 disposed within the void region and surrounded by the metallization of the first superconducting pad 211, the microheater 230 will not interfere with the RF microwave field of the superconducting qubit 210 since the first superconducting pad 211 (capacitor electrode) is essentially an equipotential region. In addition, the resistive element 232 of the microheater 230 elements is formed of a material that is resistive at room temperature, and superconducting at cryogenic temperatures so that the microheater 230 does not introduce dissipation to the superconducting qubit 210.

In addition, the microheater 230 can be fabricated with total size that is much smaller than the operating microwave wavelength of the superconducting qubit 210. For example, for an operating frequency of 5.0 GHz, the operating wavelength will be about 4.0 centimeters. In this instance, microheater 230 can be designed such that the lateral dimensions (e.g., X and Y dimensions) of the microheater 230 can be much less than ¼ of the wavelength of the operating frequency of the superconducting qubits 210 (e.g., for an operating wavelength of about 4.0 centimeters, the lateral dimension of the microheater 230 is <<1.0 cm).

Next, FIG. 2B schematically illustrates a quantum chip comprising on-chip microheater elements to enable localized thermal annealing of Josephson junctions of superconducting qubits, according to another exemplary embodiment of the disclosure. In particular, FIG. 2B is schematic top plan view of a quantum chip 200-2 which is similar to the quantum chip 200-1 of FIG. 2A, except that the quantum chip 200-2 comprises microheater elements disposed in the ground plane 202 in adjacent proximity to Josephson junctions of superconducting qubits. In particular, FIG. 2B schematically illustrates a microheater element 240 (or microheater 240) which is disposed within a patterned void region 202a of the ground plane 202 and located in relatively close proximity to the Josephson junction 213. The microheater 240 comprises a contact pad 241 and a resistive element 242, wherein the resistive element 242 is series connected between the contact pad 241 and the ground plane 202. Again, for case of illustration, the resistive element 242 is shown in FIG. 2B as a schematic symbol of a resistor. However, the resistive element 242 can be implemented using various resistive structures, exemplary embodiments of which will be explained in further detail below in conjunction with FIGS. 3A and 3B.

In an exemplary embodiment, the microheater 240 is driven by a controlled current which is applied to the microheater 240 through a pair of electrical probes, wherein a first electrical probe tip is contacted to the contact pad 241 of the microheater 240 and a second electrical probe tip is contacted to the ground plane 202. The controlled current flows through the resistive element 242 to cause the resistive element 242 to generate heat through resistive heating (joule heating) which, in turn, causes a localized heating of the region of the substrate 201 surrounding the microheater 240 through conductive heat transfer. The localized heating of the substrate 201 results in the localized thermal annealing of the Josephson junction 213 to shift the junction resistance of the Josephson junction 213. In this configuration, the localized thermal annealing of the Josephson junction 213 can be performed by driving the microheater 240 with a controlled current, without heating the Josephson junctions of neighboring superconducting qubits.

In the exemplary embodiment of FIG. 2B, the microheater 240 is positioned and designed so that the microheater 240 has no adverse effect on the operation of the superconducting qubit 210 when the quantum chip 200-2 is cooled to cryogenic temperatures. For example, with the microheater 240 disposed within a patterned void region of the ground plane 202, the microheater 240 will not interfere with the RF microwave field of the superconducting qubit 210. In addition, as noted above, the microheater 240 can be fabricated with total size that is much smaller than the operating microwave wavelength of the superconducting qubit 210.

Next, FIG. 2C schematically illustrates a quantum chip comprising on-chip microheater elements to enable localized thermal annealing of Josephson junctions of superconducting qubits, according to another exemplary embodiment of the disclosure. In particular, FIG. 2C is a schematic top plan view of a quantum chip 200-3 which is similar to the quantum chip 200-2 of FIG. 2B, except that the quantum chip 200-2 comprises an additional microheater 250 which is disposed within a void region 202b of the ground plane 202 and located in relatively close proximity to the Josephson junction 213. The microheater 250 comprises a contact pad 251 and a resistive element 252, wherein the resistive element 252 is series connected between the contact pad 251 and the ground plane 202. Again, for case of illustration, the resistive element 252 is shown in FIG. 2C as a schematic symbol of a resistor. However, the resistive element 252 can be implemented using various resistive structures, exemplary embodiments of which will be explained in further detail below in conjunction with FIGS. 3A and 3B.

It is to be noted that FIG. 2C schematically illustrates an exemplary embodiment in which the superconducting qubits of the quantum chip 200-3 each have multiple microheaters within the surrounding ground plane 202 so as to more uniformly (and locally) heat the regions of the substrate 201 on which the Josephson junctions are fabricated. For example, as schematically illustrated in FIG. 2C, the microheaters 240 and 250 are disposed in the ground plane 202 in alignment and on opposite sides of the Josephson junction 213. In an exemplary embodiment, the microheater 240 is driven by a first controlled current which is applied to the microheater 240 through a first pair of electrical probes that are contacted to the contact pad 241 and the ground plane 202, while the microheater 250 is driven by a second controlled current which is applied to the microheater 250 through a second pair of electrical probes that are contacted to the contact pad 251 and the ground plane 202. In some embodiments, a common electrical probe contact is made to the ground plane 202 such that only three electrical probes are utilized to contact the contact pads 241 and 251 and the ground plane 202 to thereby concurrently drive the microheaters 240 and 250 with the respective first and second controlled currents.

In an exemplary embodiment, the first and second controlled currents have the same current parameters (e.g., same amplitude and duration), and are applied concurrently to the respective microheaters 240 and 250 to cause the respective resistive elements 242 and 252 to generate heat through resistive heating (joule heating). The heat conduction transfer in the substrate 201 towards the Josephson junction 213, which results from the resistive heating (joule heating) of the resistive elements 242 and 253 of the microheaters 240 and 250 disposed on the opposite sides of the Josephson junction 213, provides a more uniform thermal profile for the localized thermal annealing of the Josephson junction 213, as opposed to the single microheater 240 (FIG. 2B) disposed in the ground plane 202 on one side of the Josephson junction 213.

It is to be noted that for case of illustration and explanation, FIGS. 2A, 2B, and 2C depict one superconducting qubit 210 and different positional layouts of the associated microheaters to enable localize thermal annealing of the Josephson junction 213. It is to be understood, however, that a given quantum chip would have a plurality of superconducting qubits (e.g., qubit lattice) disposed on a frontside surface of the quantum chip, wherein each superconducting qubit could have the same or similar positional layout of one or more microheaters to enable localized thermal annealing of the Josephson junctions of the superconducting qubits. Furthermore, in some embodiments, the exemplary superconducting qubit 210 shown in FIGS. 2A, 2B, and 2C can have a microheater disposed in each of the first and second superconducting pads 211 and 212. In other embodiments the exemplary superconducting qubit 210 can have a plurality of microheaters located in at least one of the first and second superconducting pads 211 and 212 (capacitor pads), and within one or more region of the ground plane 202 in proximity to the Josephson junction 213.

In all exemplary configurations, the on-chip microheater elements that are associated with a given superconducting qubit should be arranged and configured to enable localized thermal annealing of the given superconducting qubit, while having a negligible effect on the RF properties of the given superconducting qubit, as well as neighboring superconducting qubits and other microwave circuitry of the quantum chip. In particular, the on-chip microheaters should introduce no stray capacitance or inductance on the superconducting device of the quantum chip, and have a negligible amount of microwave loss.

Moreover, while exemplary embodiments of the disclosure (such as shown in FIGS. 2A, 2B, and 2C) are discussed in the context of transmon qubits for illustrative purposes, a quantum chip may comprise other types of superconducting qubits which comprise, e.g., one or more Josephson junctions and superconducting capacitors, such as fluxonium qubits, multimode qubits (e.g., two-junction qubits, or tunable coupling qubits), and other types of fixed-frequency qubits or tunable-frequency qubits which are suitable for a given application. For example, the superconducting qubit 210 (fixed-frequency transmon qubit) can be made flux-tunable by including an additional Josephson junction coupled in parallel with the Josephson junction 213, thereby forming a SQUID with a superconducting loop through which a magnetic flux is threaded to tune the transition frequency of the superconducting qubit. In all instances, irrespective of the type of superconducting qubit, the positional layout of the associated microheaters of a given superconducting qubit can be optimized to generate a suitable thermal profile to enable localized thermal annealing the one or more Josephson junctions of the given superconducting qubit by virtue of the thermal energy generated from the resistive heating of the associated microheaters.

Various exemplary architectures and layouts of on-chip microheater elements to enable localized thermal annealing of Josephson junctions will now be discussed in further detail in conjunction with FIGS. 3A, 3B, 3C, and 3D. For example, FIG. 3A schematically illustrates an exemplary architecture and layout 300-1 of an on-chip microheater element on a quantum chip, according to an exemplary embodiment of the disclosure. In particular, FIG. 3A schematically illustrates a portion of a quantum chip comprising a substrate 301, a patterned metallization feature 302 disposed on a surface of the substrate 301, and an on-chip microheater element 310 (or microheater 310) disposed on the surface of the substrate 301 within a patterned void region 302a of the patterned metallization feature 302. The microheater 310 comprises a contact pad 311 and a resistive element 312 which is series connected to and between the contact pad 311 and the patterned metallization feature 302. The patterned metallization feature 302 can be a patterned superconducting capacitor pad of a superconducting qubit, or a patterned ground plane on the surface of the substrate 301.

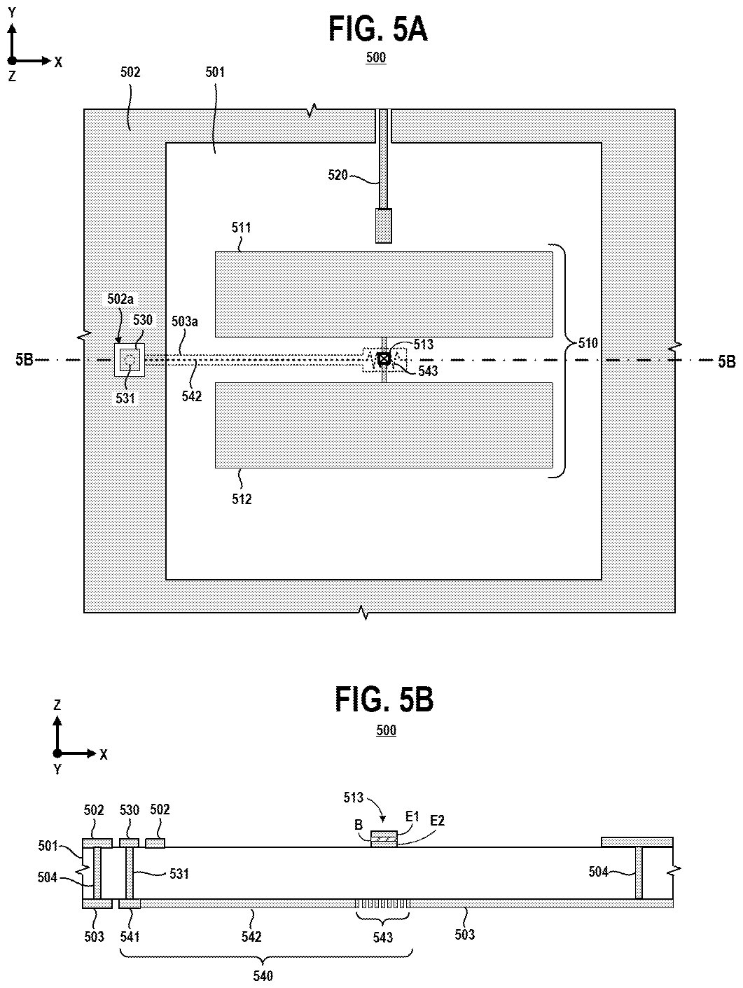

In the exemplary embodiment shown in FIG. 3A, the resistive element 312 comprises a patterned metal trace which is configured to generate heat through resistive heating (Joule heating) when a controlled current is applied to the microheater 310. The exemplary resistive element 312 comprises a metal trace having a meander geometric pattern. In other embodiments, the resistive element of a microheater may comprise a patterned metal trace with other geometric patterns, including, but not limited to, serpentine patterns, square-shaped patterns, annular-shaped patterns, etc., exemplary embodiments of which are shown and described in further detail below in conjunction with FIGS. 4A, 4B, and 4C.

It is to be noted that the exemplary microheaters 230, 240, and 250 of FIGS. 2A, 2B, and 2C can be implemented using the exemplary architecture of the microheater 310 shown in FIG. 3A. As noted above, to ensure that the microheater 310 does not adversely interfere with the RF microwave field of the associated superconducting qubit, the microheater 310 is fabricated with a size that is much smaller than the operating microwave wavelength of the associated superconducting qubit. For example, as shown in FIG. 3A, lateral dimensions (e.g., X and Y dimensions) of the patterned void region 302a will have a width (W) which is much less than ¼ of the wavelength of the operating frequency of the associated superconducting qubit (e.g., for an operating frequency of 5.0 GHz and associated operating wavelength of about 4.0 centimeters, the lateral dimension W<<1.0 cm).

Next, FIG. 3B schematically illustrates an exemplary architecture and layout 300-2 of an on-chip microheater element on a quantum chip, according to another exemplary embodiment of the disclosure. In particular, similar to FIG. 3A, the exemplary architecture and layout 300-2 of FIG. 3B schematically illustrates a portion of a quantum chip comprising a substrate 301, a patterned metallization feature 302 disposed on a surface of the substrate 301, and an on-chip microheater element 320 (or microheater 320) disposed on the surface of the substrate 301 within a patterned void region 302a of the patterned metallization feature 302. The microheater 320 comprises a contact pad 321 and a resistive element 322 which is series connected to and between the contact pad 321 and the patterned metallization feature 302. The patterned metallization feature 302 can be a patterned superconducting capacitor pad of a superconducting qubit, or a patterned ground plane on the surface of the substrate 301.

In the exemplary embodiment shown in FIG. 3B, the resistive element 322 comprises a doped-substrate resistive element which is formed by doping a region of the substrate 301 to form a semiconductor resistor that is configured to generate heat through resistive heating (Joule heating) when a controlled current is applied to the microheater 320. The doped-substrate resistive element 322 can be fabricated using known techniques such as, e.g., adding dopants to a silicon substrate to form a doped semiconductor resistor. More specifically, as is known in the art, the electrical properties of a silicon crystal lattice can be modified by adding dopants into the silicon crystal lattice to, e.g., form a semiconductor resistor. The resistivity of the semiconductor material is a function of the doping level, wherein a given semiconductor resistor can be fabricated with a well-defined resistor value based on factors such as the cross-sectional area, length, and doping level, of the doped region of the substrate. In this regard, any suitable fabrication process can be implemented to form the doped-substrate resistive element 322 which has a desired resistance and power handling capability.

Preferably, the doped-substrate resistive element 322 is fabricated to have no dissipative loss at cryogenic temperatures, which allows the microheater 320 with the doped-substrate resistive element 322 to be disposed within a superconducting capacitor pad of a superconducting qubit (such as shown in FIG. 2A) without having any adverse impact on the performance of the superconducting qubit when operating at cryogenic temperatures. On the other hand, if the doped-substrate resistive element 322 does have some dissipative loss at cryogenic temperatures, the microheater 320 with the doped-substrate resistive element 322 can be disposed within a void region of the ground plane of the quantum chip (such as shown in FIGS. 2B and 2C) assuming there is no RF field in such region which would be adversely affected by dissipative loss of the doped-substrate resistive element 322 at cryogenic temperatures.

Next, FIG. 3C schematically illustrates an exemplary architecture and layout 300-3 of an on-chip microheater element on a quantum chip, according to another exemplary embodiment of the disclosure. In particular, similar to FIGS. 3A and 3B, the exemplary architecture and layout 300-2 of FIG. 3C schematically illustrates a portion of a quantum chip comprising a substrate 301, a patterned metallization feature 302 disposed on a surface of the substrate 301, and an on-chip microheater element 330 (or microheater 330) disposed on the surface of the substrate 301 within a patterned void region 302a of the patterned metallization feature 302. The microheater 330 comprises an alternative architecture in which the microheater 330 comprises a microfabricated pickup coil 331 (e.g., a planar inductor element) and a resistive element 332 which is series connected to and between the pickup coil 331 and the patterned metallization feature 302. Again, the patterned metallization feature 302 can be a patterned superconducting capacitor pad of a superconducting qubit, or a patterned ground plane on the surface of the substrate 301.

The exemplary architecture of the microheater 330 as shown in FIG. 3C utilizes the pickup coil 331 in place of a probe contact pad, which allows the microheater 330 to be driven inductively without a probe contact. In this configuration, the controlled current would be applied to the microheater 330 through a mutual inductance between the pickup coil 331 and a corresponding patterned coil (e.g., planar inductor element) disposed on a surface of the probe card, as opposed to galvanically through probe tips. In this instance, the controlled current can be a controlled AC current that is sourced to the patterned coil on the probe card, wherein the patterned coil on the probe card would be disposed in adjacent proximity to the pickup coil 331 of the microheater. This allows the controlled AC current applied to the patterned coil of the probe card to be inductively coupled to the pickup coil 331 and thereby cause current flow through the resistive element 332 to generate heat through resistive heating. FIG. 3C schematically illustrates an exemplary embodiment in which the pickup coil 331 comprises a square-shaped planar inductor. In other embodiments, the pickup coil 331 can be designed to have other planar inductor geometries which include, but not limited to, circular-shaped planar inductors, hexagonal-shaped planar inductors, octagonal-shaped planar inductors, etc.

Next, FIG. 3D schematically illustrates an exemplary architecture and layout 300-4 of an on-chip microheater element on a quantum chip, according to another exemplary embodiment of the disclosure. In particular, similar to the exemplary embodiments discussed above, FIG. 3D schematically illustrates a portion of a quantum chip comprising a substrate 301, a patterned metallization feature 302 disposed on a surface of the substrate 301, and an on-chip microheater element 340 (or microheater 340) disposed on the surface of the substrate 301 within a patterned void region 302a of the patterned metallization feature 302. The patterned metallization feature 302 can be a patterned superconducting capacitor pad of a superconducting qubit, or a patterned ground plane on the surface of the substrate 301.

The microheater 340 comprises a first contact pad 341-1, a second contact pad 341-2, and a resistive element 342 connected in series to and between the first and second contact pads 341-1 and 341-2. The first and second contact pads 341-1 and 341-2 are disposed within the patterned void region 302a of the patterned metallization feature 302 and are, therefore, electrically isolated from the patterned metallization feature 302. In this exemplary embodiment, the microheater 340 is entirely electrically isolated from the patterned metallization feature 302, whereby no current needs to be driven through the patterned metallization feature 302 to actuate the microheater 340. Instead, a pair of electrical probes are utilized to make contact to the first and second contact pads 341-1 and 341-2 and to apply a controlled current which flows through the resistive element 342. This embodiment allows the microheater 340 to be thermally isolated from the surrounding patterned metallization feature 302, except for heat conducted through the substrate 301. As schematically illustrated in FIG. 3D, the resistive element 342 comprises a patterned metal trace. However, in other embodiments, the resistive element 342 can be a doped-substrate resistive element or other resistive element, which is connected to and between the first and second contact pads 341-1 and 341-2, and which is configured to generate heat when a controlled current is applied to the microheater 340.

It is to be noted that while FIGS. 3A, 3C, and 3D illustrate exemplary embodiments in which the resistive elements comprise certain metal trace geometries (e.g., meander geometry), it is to be understood that an on-chip microheater can be implemented with other metal trace geometries such as shown in FIGS. 4A, 4B, and 4C. For example, FIG. 4A schematically illustrates an exemplary resistive element 400 which comprises a serpentine pattern (e.g., a dual meander geometry). FIG. 4B schematically illustrates an exemplary resistive element 401 which comprises a square-shaped pattern (e.g., a double spiral square geometry). FIG. 4C schematically illustrates an exemplary resistive element 402 which comprises an annular-shaped pattern (e.g., a double spiral geometry). It is to be noted that the exemplary geometric metal trace patterns of resistive elements as described herein are non-limiting exemplary embodiments of different metallic trace patterns/geometries that can be utilized to implement resistive elements of microheaters, and that many other types of suitable metal trace patterns/geometries can be implemented to provide desired thermal profiles for localized thermal annealing of Josephson junctions, depending on the application.

It is to be further noted that as an alternative embodiment of the microheater structure shown in FIG. 3C, a microheater can be fabricated using a metallic trace pattern/geometry which serves a dual purpose of (i) operating as a pickup coil for receiving a controlled current, and (ii) operating a resistive element to generate heat via Joule current as a result of the applied controlled current. Such a design is possible when the pickup coil can be properly designed to provide sufficient inductive coupling with a corresponding coil on the probe card, while also providing sufficient resistance and power handling to service as a resistive element that can generate sufficient thermal energy via Joule heating to enable localized thermal annealing of a Josephson junction.

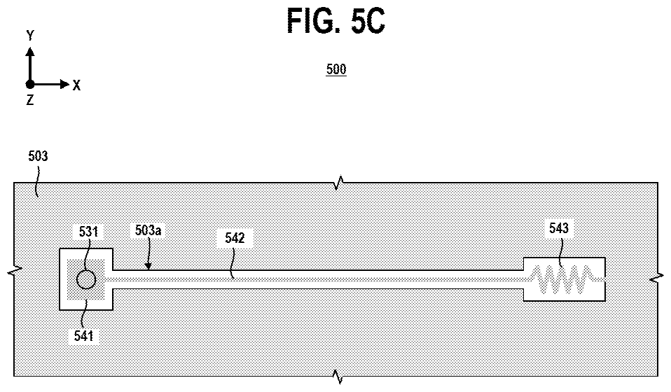

It is to be noted that FIGS. 2A, 2B, and 2C schematically illustrate exemplary embodiments in which the on-chip microheaters are disposed on the same surface (e.g., frontside surface) of the quantum chip along with the superconducting qubits and readout resonators, and other possible superconducting quantum devices. However, in other embodiments, the on-chip microheaters can be disposed on a backside surface of the quantum chip, and contacted using contact pads that are formed on the frontside of the quantum chips and through-substrate vias (TSVs) that are formed in the substrate. For example, FIGS. 5A, 5B, and 5C are schematic views of a quantum chip comprising backside microheater elements to enable localized thermal annealing of frontside Josephson junctions of superconducting qubits, according to an exemplary embodiment of the disclosure. FIG. 5A is a schematic top plan view of quantum chip 500 showing a frontside surface of the quantum chip 500. FIG. 5B is a schematic cross-sectional side view of the quantum chip 500 along line 5B-5B in FIG. 5A. FIG. 5C is a schematic plan view of a backside surface of the quantum chip 500.

As collectively shown in FIGS. 5A, 5B, and 5C, the quantum chip 500 comprises a substrate 501, a frontside ground plane 502, a backside ground plane 503, and a plurality of ground TSVs 504 which connect the frontside ground plane 502 and the backside ground plane 503. The quantum chip 500 further comprises a superconducting qubit 510, a qubit readout resonator 520, and a frontside contact pad 530 disposed on the frontside surface of the quantum chip 500. The frontside contact pad 530 is disposed within a patterned void region 502a of the frontside ground plane 502. The frontside contact pad 530 serves as a frontside contact to a backside microheater element 540 (or backside microheater 540). The superconducting qubit 510 comprises a first superconducting pad 511, a second superconducting pad 512 (superconducting capacitor pads), and a Josephson junction 513 coupled to, and disposed between, the first and second superconducting pads 511 and 512. Similar to the exemplary embodiments discussed above, the superconducting qubit 510 comprises a transmon qubit which comprises a superconducting capacitor structure connected in parallel with a Josephson junction, wherein the first and second superconducting pads 511 and 512 comprise capacitor electrodes of a coplanar capacitor structure of the superconducting qubit 510. As shown in FIG. 5B, the Josephson junction 513 comprises a first superconducting electrode E1, a second superconducting electrode E2, and a non-superconducting barrier layer B (e.g., oxide layer) disposed between the first and second superconducting electrodes E1 and E2.

The quantum chip 500 further comprises a TSV 531 that connects the frontside contact pad 530 to the backside microheater 540. The backside microheater 540 comprises a backside contact pad 541, a metal trace 542, and a resistive element 543. The metal trace 542 connects the backside contact pad 541 to the resistive element 543. The resistive element 543 is series connected to and between the metal trace 542 and the backside ground plane 503. The resistive element 543 can be implemented using any suitable resistive structure, such as any one of the exemplary resistive structures discussed herein (e.g., FIGS. 3A, 3B, and 4A-4C). As schematically shown in FIG. 5C, the backside contact pad 541, the metal trace 542, and the resistive element 543 are disposed within a patterned void region 503a of the backside ground plane 503, with one end of the resistive element 543 connected to the backside ground plane 503. The frontside contact pad 530, the TSV 531, the backside contact pad 541, and the metal trace 542 collectively provide an electrical path from the frontside of the quantum chip 500 to the resistive element 543 on the backside of the quantum chip 500.

It is to be appreciated that FIGS. 5A-5C illustrate an exemplary embodiment in which the resistive element 543 of the backside microheater 540 is vertically aligned with the Josephson junction 513 on the frontside of the quantum chip 500, to thereby place the resistive element 543 in close proximity to the Josephson junction 513. In this instance, the distance between the resistive element 543 and the Josephson junction 513 is based on the thickness of the substrate 501, which can be made very thin, e.g., 10-50 microns.

In an exemplary mode of operation, the backside microheater 540 is driven by a controlled current which is applied to the backside microheater 540 through a pair of electrical probes, wherein a first electrical probe tip is contacted to the frontside contact pad 530 and a second electrical probe tip is contacted to the frontside ground plane 502 (which is galvanically connected to the backside ground plane 503 by the ground TSVs 504). The controlled current flows along the electrical path from the frontside contact pad 530 to the resistive element 543 through the TSV 531, the backside contact pad 541, and the metal trace 542, wherein the controlled current flows through the resistive element 543 to cause the resistive element 543 to generate heat through resistive heating (Joule heating). The Joule heating of the resistive element 543 causes a localized heating of the region of the substrate 501 below the Josephson junction 513, through conductive heat transfer. The localized heating of the substrate 501 below the Josephson junction 513 results in the localized thermal annealing of the Josephson junction 513 to cause a shift in the junction resistance of the Josephson junction 513.

In an alternative mode of operation, the backside microheater 540 is driven by a controlled current which is applied to the backside microheater 540 through a pair of electrical probes contacting the back side of the quantum chip 500. In particular, a first electrical probe tip is contacted to the backside contact pad 541, and a second electrical probe tip is contacted to the backside ground plane 503. With this configuration, a controlled current will flow along an electrical path from the backside contact pad 541 to the backside ground plane 503 through the metal trace 542 and the resistive element 543 to cause the resistive element 543 to generate heat through resistive heating. In this regard, the operation of the backside microheater 540 is the same irrespective of whether the backside microheater 540 is driven using electrical probes contacting the frontside or the backside of the quantum chip 500.

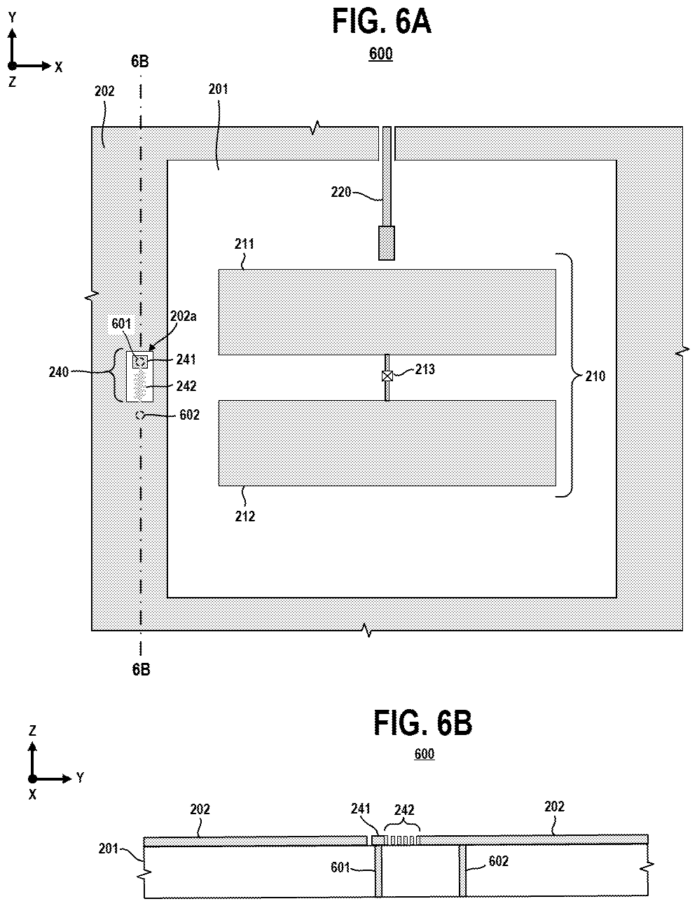

FIGS. 6A and 6B are schematic views of a quantum chip comprising on-chip microheater elements to enable localized thermal annealing of Josephson junctions of superconducting qubits, and wiring to shunt the microheater elements to ground when the quantum chip is packaged, according to an exemplary embodiment of the disclosure. FIG. 6A is a schematic top plan view of quantum chip 600 showing a frontside surface of the quantum chip 600, and FIG. 6B is a schematic cross-sectional side view of the quantum chip 600 along line 6B-6B in FIG. 6A.

The quantum chip 600 is similar to the quantum chip 200-2 shown in FIG. 2B, the details of which will not be repeated. However, FIGS. 6A and 6B illustrate an exemplary configuration in which the quantum chip 600 has a plurality of TSVs 601 and 602 formed in the substrate 201. The TSV 601 is formed in contact with the contact pad 241 of the microheater 240, and the TSV 602 is formed in contact with the frontside ground plane 202. As noted above, the microheater 240 is utilized to generate heat energy for localized thermal annealing of the Josephson junction 213 by driving the microheater 240 with a controlled current that is applied to the microheater 240 through a pair of electrical probes, wherein a first electrical probe tip is contacted to the contact pad 241 and a second electrical probe tip is contacted to the ground plane 202, which are disposed on the frontside of the quantum chip 600.

At some later stage of fabrication, subsequent to performing a tuning process to tune the junction resistance of the Josephson junction 213, the quantum chip 600 can be packaged with other layers (e.g., either a backside and/or front-side multilevel wiring structure or circuit board) to cause the microheater 240 to be shorted to ground. For example, in some embodiments, a backside ground plane would be disposed in contact with the backside surface of the quantum chip 600, wherein the backside ground plane would be connected to the first and second TSVs 601 and 602 thereby causing the microheater 240 to be shorted to ground. In some embodiments, additional frontside wiring would be disposed in contact with portions of the frontside surface of the quantum chip 600, wherein the frontside wiring would be configured to shunt the contact pad 241 directly to the ground plane 202. In such configurations, the microheater 240 would be shorted to ground, thereby rendering the microheater 240 inert with respect to RF fields such that the microheater 240 would have no effect on the operation of the superconducting qubit 210.

In other embodiments, when on-chip microheaters are disposed in a frontside ground plane or a backside ground plane of a quantum chip, each microheater can be driven by respective wiring of a frontside wiring layer and/or a backside wiring layer, wherein the wiring is permanently connected to the microheaters to enable access to the microheaters after the quantum chip is packaged with the frontside and/or backside wiring layers of other package layers/structures. For example, in some embodiments, the contacts pads of on-chip microheaters can be attached to package wiring using wire-bonds, bump-bonds, contact-pins or other means of electrically connecting the contact pads to package and circuit board wiring. In such embodiments, the package wiring can be configured to enable access to the microheaters though external I/O pins and package traces of an interposer and/or other chip modules to which the quantum chip is attached, so that the microheaters can be driven (post packaging) with controlled currents applied to the package wiring to perform further localized thermal annealing of Josephson junctions, as needed, to make small fine tune shifts of the junction resistances. In this configuration, the microheaters can be utilized to enable localized thermal annealing of the associated Josephson junctions of the quantum chip, after the quantum chip is packaged, or even when the quantum chip is installed in dilution refrigerator, which is not possible using LASIQ or any other known method. When the microheaters are permanently wired (e.g., via DC wiring) for access, post packaging of the quantum chip, the wiring to the microheaters can incorporate ground shield layers and have in-line low pass filters with extremely low cutoff frequences to filter out noise at RF frequences that could propagate to the microheaters and potentially perturb the quantum states of the superconducting qubits.

It is to be appreciated that various tuning protocols can be implemented to tune Josephson junctions to respective target junction resistances by localized thermal annealing of the Josephson junctions using on-chip microheater elements. In general, a tuning protocol may comprise an iterative process that involves performing junction resistance measurements to measure the normal state resistances of the Josephson junctions, and driving the microheaters with controlled currents to cause localized thermal annealing of the Josephson junctions to shift the junction resistance of each Josephson junction to a respective target junction resistance R_{target}. As noted above, the control system 110 (FIG. 1) is configured to control the prober unit 130 to perform junction resistance measurements, as well as apply controlled currents to drive the on-chip microheater elements when tuning the Josephson junctions via localized thermal annealing.

For example, FIG. 7A schematically illustrates a method for measuring a junction resistance of a Josephson junction, according to an exemplary embodiment of the disclosure. In particular, FIG. 7A schematically illustrates a method 700-1 for utilizing a 4-probe configuration to perform a 4-wire resistance measurement (or Kelvin resistance measurement) to measure the junction resistance of a Josephson junction. In some embodiments, FIG. 7A schematically illustrates an exemplary embodiment and configuration of the SMU 112 and the electrical probes 131 of the prober unit 130 (FIG. 1) to measure a junction resistance of a Josephson junction. For example, FIG. 7A schematically illustrates an exemplary embodiment of a superconducting qubit 710 (e.g., a transmon qubit) comprising a first superconducting capacitor pad 711, a second superconducting capacitor pad 712, and a Josephson junction 713. In addition, FIG. 7A schematically illustrates an exemplary embodiment of a source measurement unit 720 (or SMU 720) which comprises current generator circuitry 722 and voltage measurement circuitry 724, as well as an exemplary 4-wire electrical probe configuration of a probe card which comprises a first electrical probe 730-1, a second electrical probe 730-2, a third electrical probe 730-3, and a fourth probe 730-4 (which are schematically illustrated in in FIG. 7A as circles that represent probe tips of the corresponding electrical probes).

As schematically illustrated in FIG. 7A, the probe tips of the first and second electrical probes 730-1 and 730-2 are aligned and in contact with the first superconducting capacitor pad 711 of the superconducting qubit 710, and the probe tips of the third and fourth electrical probes 730-3 and 730-4 are aligned and in contact with the second superconducting capacitor pad 712 of the superconducting qubit 710. In this embodiment, the first and second superconducting capacitor pads 711 and 712 of the superconducting qubit 710 serve as the contact pads of the Josephson junction 713 on which the probe tips of the electrical probes 730-1, 730-2, 730-3, and 730-4 are landed to perform junction resistance measurements. The first and third electrical probes 730-1 and 730-3 are electrically connected to the voltage measurement circuitry 724 of the SMU 720, and the second and fourth electrical probes 730-2 and 730-4 are electrically connected to the current generator circuitry 722 of the SMU 720.

In some embodiments, the SMU 720 is configured to perform a 4-wire (Kelvin) resistance measurement to measure the junction resistance of the Josephson junction 713 by a process which comprises (i) utilizing the current generator circuitry 722 to generate and output a current pulse (e.g., DC pulse) to cause a current to flow from the second electrical probe 730-2 to the fourth electrical probe 730-4 (or vice versa) through the Josephson junction 713, and (ii) utilizing the voltage measurement circuitry 724 and the first and third electrical probes 730-1 and 730-3 to detect and measure a voltage drop (V) across the Josephson junction 713 as a result of the current (I) flowing through the Josephson junction 713. The junction resistance Rₙ of the Josephson junction 713 is determined based on Ohm's Law, i.e., Rₙ=V/I. In some embodiments, the DC current that is used to perform a junction resistance measurement comprises a pulse amplitude and duration which is sufficient to perform a 4-wire junction resistance measurement, without causing a shift in the junction resistance of the Josephson junction 713.

Next, FIG. 7B schematically illustrates a method for driving a microheater element to generate heat for localized thermal annealing of a Josephson junction, according to an exemplary embodiment of the disclosure. For purposes of illustration, FIG. 7B schematically illustrates an exemplary method of utilizing the SMU 720 to drive the exemplary microheater 310 of FIG. 3A. In addition, FIG. 7B schematically illustrates an exemplary embodiment of utilizing a pair of electrical probes (of a probe card) including a first electrical probe 740-1 and a second electrical probe 740-2, which are schematically illustrated in in FIG. 7B as circles that represent probe tips of the corresponding electrical probes, to drive the microheater 310 with a controlled current that is generated by the current generator circuitry 722 of the SMU 720.

In particular, as schematically shown in FIG. 7B, the probe tip of the first electrical probe 740-1 is aligned and in contact with the contact pad 311 of the microheater 310, and the probe tip of the second electrical probe 740-2 is aligned and in contact the patterned metallization feature 302 which, as noted above, can be a superconducting capacitor pad of a superconducting qubit, or a patterned ground plane on the surface of the substrate 301. In an exemplary embodiment, the microheater 310 is driven by a controlled current which is generated by the current generator circuitry 722 and applied to the microheater 310 through the pair of electrical probes 740-1 and 740-2. The controlled current flow through the resistive element 312 causes the resistive element 312 to generate heat through Joule heating which, in turn, causes a localized heating of the region of the substrate 301 surrounding the microheater 310 through conductive heat transfer. The localized heating of the substrate 301 results in the localized thermal annealing of a Josephson junction that is disposed in proximity to the microheater 310.

In an exemplary embodiment, the electrical probes 730-1, 730-2, 730-3, 730-4, 740-1, and 740-1 shown in FIGS. 7A and 7B are disposed on the same probe card such that the probe pins for performing junction resistance measurement and the probe pins for driving on-chip microheaters with controlled current can be concurrently contacted to corresponding contact pads on the surface of the quantum chip. In this instance, Josephson junctions can be probed for resistance measurement concurrently by applying controlled currents to on-chip microheaters for localized thermal annealing of Josephson junctions. For example, during a tuning process, a probe card with the appropriate arrangement of probe pins can be contacted to a quantum chip, and the microheater(s) associated with a given superconducting qubit can be driven with a controlled current to thermally anneal the Josephson junction(s) of the given superconducting qubit, and then the Josephson junction(s) can be probed to measure junction resistance, without having to realign the probe card. In some instances, a junction resistance measurement operation can be performed on a given Josephson junction concurrently with a thermal annealing operation so to track the junction resistance and determine when the junction resistance reaches a target junction resistance, in which case the tuning current can be terminated. In other embodiments, the junction resistance measurements and tuning operations are performed separately, which allows the Josephson junction to cool down after a tuning operation before measuring the junction resistance.

It is to be noted that a wide range of thermal profiles for localized thermal annealing of Josephson junctions can be achieved based on factors such as the number of microheaters that are utilized, the positional arrangement of such microheaters, and the parameters (e.g., magnitude, duration, etc.) of the controlled currents (e.g., DC current pulses, or AC current pulses) that are used to drive the on-chip microheaters to generate sufficient Joule heating for localized thermal annealing of Josephson junctions. For example, different positional arrangements and/or structural configurations of on-chip microheaters can be utilized to provide different thermal profiles for laser annealing superconducting quantum devices (e.g., qubits) which have different geometries of Josephson junction. It is to be noted that the term “thermal profile” or “localized thermal profile” as used herein refers to a temperature profile (thermal signature) or localized temperature profile of a region of a substrate (e.g., quantum chip substrate) which includes a one or more Josephson junctions to be thermally annealed, which is generated as a result of driving one or more on-chip microheaters that are disposed in local proximity to the one or more Josephson junctions.

The temperature profile generated by a given on-chip microheater will depend on various factors, including, e.g., electrical, thermal, and material properties of the resistive element, as well as the geometric design of the resistive element. By way of example, consider the exemplary on-chip microheater element 310 (FIG. 3A) in which the resistive element 312 comprises a meandering wire pattern that is formed of a superconducting metal film such as niobium with a wire thickness of 0.2 μm, and the substrate 301 comprises a silicon substrate with a thickness of 90 μm. Assume that the meandering wire of the resistive element 312 has a width of 1.0 μm and a total length of 0.2 mm, and has a footprint area of 20 μm×20 μm. Since niobium has a resistivity of 0.2μΩ·m, the resistive element 312 would have a total resistance (R) of 200Ω.

Assume further that a given Josephson junction to be annealed is disposed 50 μm away from the resistive element 312 of the microheater 310 on the surface of the silicon substrate, and that a controlled current (I) of 0.15 amps is applied the microheater 310. In this instance, the resistive element 312 of the microheater 310 would produce a heating power of 4.5 watts (W) (i.e., P(W)=I²·R=0.15²·200). In addition, the total voltage across the resistive element 312 (e.g., from one end of the meandering wire to the other end) would be 30 V (i.e., V=I·R=0.15·200=30V). The electric field produced within the substrate 301 (e.g., silicon substrate) under the 20 μm×20 μm footprint areal of the resistive element 312 would be at least 10 times smaller than the dielectric breakdown strength of the substrate 301, which is 20 volts per micron.

The 4.5 W of heat energy produced by the resistive element 312 would flow from the resistive element 312 uniformly in all directions into the substrate 301 via thermal conduction. Assume that the backside surface of the substrate 301, and anywhere within the substrate 301 at a distance of 90 μm microns from the resistive element 312, is at room temperature. The approximate temperature profile within the substrate 301 can be determined analytically. For example, assume that the silicon substrate has an average thermal conductivity of about 100 watts per meter-Kelvin (W/m·K) at temperatures above room temperature. Under these conditions, the region of the substrate 301, which has the Josephson junction at a distance of 50 μm from the resistive element 312, would reach a temperature of about 100° Celsius (C), which is sufficient for thermally annealing the Josephson junction. Moreover, under these conditions, the temperature of the resistive element 312 of the microheater 310 would reach or exceed 600° C., which is well below the melting temperature of niobium (which is 2477° C.) and the melting temperature of silicon (which is 1414° C.).

It is to be noted that the above noted exemplary parameters are meant to provide a non-limiting exemplary embodiment for configuring a given microheater, and controlled current to drive the microheater to enable localized thermal annealing of a Josephson junction. However, it is to be understood that a given Josephson junction can be heated to higher temperatures by, e.g., (i) constructing and implementing on-chip microheaters with resistive elements having resistances that are greater than 200Ω, (ii) driving the microheaters with controlled currents having greater magnitudes, and/or (iii) utilizing multiple microheaters to generate heat energy that is combined to generate a larger thermal profile for localized thermal annealing of a given Josephson junction (or group of Josephson junctions). In all instances, the voltage drop across the resistive elements of the on-chip microheaters should be kept low enough to avoid dielectric breakdown of the substrate. In addition, the temperatures resulting from Joule heating should be kept low enough to avoid damage to the on-chip microheaters (e.g., melting the resistive elements, etc.).

As noted above, in some embodiments, a tuning calibration process is implemented to obtain tuning calibration data to facilitate localized thermal annealing of Josephson junctions using on-chip microheaters. In general, an exemplary tuning calibration process involves performing trial thermal annealing operations on test quantum devices (e.g., superconducting qubits) having test Josephson junctions and associated test microheater elements which are disposed in proximity to the test Josephson junctions. The trial thermal annealing operations are performed using different (unique) combinations of thermal annealing parameters to generate different thermal profiles for localized thermal annealing of the test Josephson junctions, and determining and analyzing information regarding resulting shifts in junction resistances of the test Josephson junctions, based on the different thermal profiles. For purposes of illustration, exemplary tuning calibration techniques for generating tuning calibration data to support localized thermal annealing of Josephson junctions using on-chip microheaters will now be discussed in further detail in conjunction with FIGS. 8, 9, and 10.

For example, FIG. 8 illustrates a flow diagram of a calibration process for generating tuning calibration data to facilitate localized thermal annealing of Josephson junctions using on-chip microheaters, according to an exemplary embodiment of the disclosure. In some embodiments, FIG. 8 illustrates a calibration process which can be performed using the system 100 of FIG. 1 with the control system 110 executing a calibration algorithm. Referring to FIG. 8, a quantum chip is placed on the X-Y-Z stage 132 of the prober unit 130, and the control system 110 commences an automated calibration process (block 800). As in the initial phase, the quantum chip is aligned to a probe card by X-Y positioning of the X-Y-Z stage 132, and contact is made between the quantum chip and the probe card by Z positioning the X-Y-Z stage 132 to make sufficient contact between the electrical probes (probe pins) of the probe card and contact pads on the quantum chip, to enable junction resistance measurements and apply controlled currents to drive test microheaters, as descried above in conjunction with FIGS. 7A and 7B.

In some embodiments, the quantum chip comprises a set of test quantum devices (e.g., superconducting qubits) where each test quantum device comprises one or more test Josephson junctions and associated test microheater elements which are disposed in proximity to the test Josephson junctions. For example, the set of test quantum devices can include (i) multiple instances of the exemplary superconducting qubit 210 and associated microheater 230, as shown in FIG. 2A, (ii) multiple instances of the exemplary superconducting qubit 210 and associated microheater 240, as shown in FIG. 2B, and/or (iii) multiple instances of the exemplary superconducting qubit 210 and associated microheaters 240 and 250, as shown in FIG. 2C, etc. Moreover, in some embodiments, the set of test quantum devices can include multiple instances of the exemplary superconducting qubit 510 and associated backside microheater 540, as shown in FIGS. 5A-5C.

The test quantum devices with the associated test Josephson junctions and test microheater elements are representative of actual quantum devices with Josephson junctions that are to be tuned by localized thermal annealing using associated on-chip microheater elements, wherein the calibration data is utilized to configure controlled currents for driving the associated on-chip microheater elements to achieve a target thermal profile for localized thermal annealing of the Josephson junctions. In some embodiments, the quantum chip is a test chip, e.g., a sister chiplet from a same wafer having quantum devices with associated Josephson junctions that were fabricated using the same fabrication processes (e.g., junction evaporation process) as the Josephson junctions on the actual quantum chip. In this regard, the test Josephson junctions on the test chip (e.g., sister chiplet) are deemed to correspond to the Josephson junctions on the actual chip, since the test Josephson junctions (and associated test microheaters) and the actual Josephson junctions (and associated microheaters) are fabricated using the same or similar processes. In this regard, the test Josephson junctions are assumed to have the same, or substantially the same, or similar tuning characteristics as the Josephson junctions on the actual chip which are to be tuned using controlled currents to drive the on-chip microheaters, which controlled currents are configured based on the calibration data obtained from the calibration operations performed on the test Josephson junctions on the test chip.

In other embodiments, the calibration process may be implemented using a set of test quantum devices with associated test Josephson junctions and test microheater elements, which reside on the same quantum chip which has the actual Josephson junctions that are to be tuned. For example, the set of test quantum devices with associated test Josephson junctions and test microheater elements can be a dedicated test array of quantum devices that are formed on the quantum chip and located, e.g., in a kerf of the quantum chip. In this regard, the set of test quantum devices with associated test Josephson junctions and test microheater elements on the quantum chip correspond to the actual Josephson junctions on the same quantum chip. Since the collection of test quantum devices and the actual quantum devices (residing on the same quantum chip) are fabricated using the same fabrication processes, the test Josephson junctions and actual Josephson junctions (to be tuned) will have the same, or substantially the same, or similar tuning characteristics with respect to the localized thermal annealing achieved by using the associated test and actual microheater elements.

The calibration process proceeds by performing a series of trial thermal annealing operations on the test Josephson junctions to obtain calibration data with respect to changes (shifts) in junction resistances of the test Josephson junction, which are achieved as a result of the localized thermal annealing of the test Josephson junctions with different (unique) combinations of thermal annealing parameters (block 801). Depending on the calibration process, the thermal annealing parameters include, for example, positional layouts of test microheaters with respect to the test Josephson junctions of the test quantum devices (e.g., number of microheaters, locations of microheaters, etc.), structural configurations of the test microheaters (e.g., microheaters with resistive metal traces, or doped-substrate resistive elements, etc.), and parameters of controlled currents (e.g., DC or AC pulses) for driving the test microheaters (e.g., amplitude, duration, etc.). The different (unique) combinations of thermal annealing parameters result in different thermal profiles for localized thermal annealing of the test Josephson junctions, which can result in different responses of the test Josephson junctions with respect to the shifts in the junction resistances of the test Josephson junctions.

For example, in some embodiments, the set of test quantum devices may include a plurality of superconducting qubits, where each test superconducting qubit includes an associated test microheater element disposed in a superconducting capacitor pad (e.g., FIG. 2A) and where the test microheater element comprises a resistive element formed of a resistive metal trace (e.g., FIG. 3A). In this instance, the set of test superconducting qubits can be partitioned into a plurality of test groups, wherein for each test group of superconducting qubits, the associated microheaters are driven with a respective different controlled current to achieve different thermal profiles and associated calibration data.

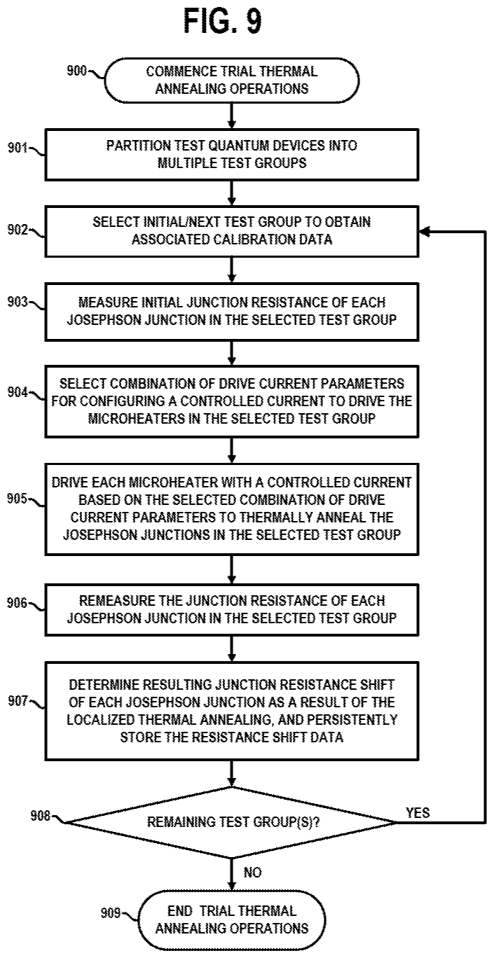

By way of example, the controlled currents for driving the microheaters can be DC current pulses with different combinations of (i) a pulse amplitude setting (e.g., selected from discrete amplitude settings ranging from 0.5 μA to 1.0 μA in multiples/increments of 0.5 μA), and (ii) a pulse duration setting (e.g., selected from discreate pulse duration settings ranging from 1.0 s to 30.0 s in multiple/increments of 1.0 s). For each controlled current with a given combination of current parameters (e.g., pulse amplitude, pulse duration, etc.), the controlled current is used to drive the test microheater elements of a given test group of superconducting qubits to cause localized thermal annealing of the associated test Josephson junctions and obtain associated tuning calibration data with regard to the resulting junction resistance shift for the different thermal profiles. An exemplary process for performing trial thermal annealing operations will be discussed in further detail below in conjunction with FIG. 9.

The calibration process analyzes the tuning calibration data to generate calibration tuning curves and associated calibration parameters (e.g., maximum tuning ranges, tuning rates, etc.) with respect to the changes in junction resistance of the test Josephson junctions, which is achieved for each of the different combinations of thermal annealing parameters (block 802). The calibration data, calibration tuning curves and associated calibration parameters (e.g., maximum tuning ranges, tuning rates, etc.) are persistently stored (block 803) and the calibration process terminates (block 804). As explained in further detail below, the tuning curves and associated calibration parameters are persistently stored for subsequent access and use in configuring controlled currents for driving on-chip microheaters for tuning corresponding Josephson junctions of quantum devices (e.g., superconducting qubits) by localized thermal annealing. The calibration data provides information that is utilized to configure controlled currents for driving microheaters to enable localized thermal annealing of Josephson junctions, which is sufficient to shift the junction resistances of the Josephson junctions to their respective target junction resistances.

FIG. 9 illustrates a flow diagram of a process for performing trial thermal annealing operations on Josephson junctions to obtain tuning calibration data, according to an exemplary embodiment of the disclosure. In some embodiments, FIG. 9 illustrates an exemplary process for implementing block 801 (FIG. 8) to perform a series of trial thermal annealing operations on the test Josephson junctions to obtain calibration data with respect to changes (shifts) in junction resistances of the test Josephson junction, which are achieved as a result of the localized thermal annealing of the test Josephson junctions with different (unique) combinations of thermal annealing parameters. The resulting calibration data represents the tuning characteristics of test Josephson junctions that are thermally annealed using different thermal profiles which result from driving test microheater elements with different controlled currents.

Referring now to FIG. 9, as noted above, an initial phase of the calibration process comprises the control system 110 commencing trial thermal annealing operations on groups of test quantum devices on a quantum chip (block 900). As noted above, in an exemplary embodiment, the quantum chip under test comprises a set of test superconducting qubits, where each test superconducting qubit comprises one or more test Josephson junctions and associated test microheater elements which are disposed in proximity to the test Josephson junctions. The set of test superconducting qubits is partitioned into multiple test groups for tuning calibration (block 901).

For example, assume that the set of test superconducting qubits includes multiple instances of the exemplary superconducting qubit 210 and the associated microheater 230 disposed in a superconducting capacitor pad, as shown in FIG. 2A, wherein the microheaters arc implemented with resistive metal traces, as shown in FIG. 3A. The number of test groups will correspond to the number of different combinations of drive current parameters for configuring controlled currents for driving the test microheaters in the different test groups. In an exemplary embodiment where the microheaters are driven with controlled DC current pulses, the drive current parameters include discrete pulse amplitudes and discrete pulse durations for configuring controlled DC current pulses for driving the test microheaters in different test groups. For example, assume that the trial thermal anneal operations are performed using controlled currents with different combinations of DC pulse amplitudes and durations including five (5) discrete pulse amplitude (A) settings (e.g., A₁, A₂, A₃, A₄, and A₅), and five (5) different pulse duration (D) settings in seconds(s) (e.g., D₁, D₂, D₃, D₄ and D₅). In this instance, the set of test superconducting qubits would be partitioned into 25 (5×5) test groups, where each test group would be associated with a given unique combination of a pulse amplitude A setting, and a pulse duration D setting (e.g., (A₁, D₁), (A₁, D₂), (A₁, D₃), (A₁, D₄), (A₁, D₅), (A₂, D₁), (A₂, D₂), (A₂, D₃), etc.). Moreover, each test group would have a sufficient number of test devices (e.g., 3, 4, 5, 6, 7, etc.) to obtain an amount of calibration data with statistical significance.

The calibration process selects an initial test group to perform trial thermal anneal operations on the test Josephson junctions in the selected test group to obtain calibration data (block 902). The calibration process then proceeds to perform resistance measurements to measure an initial junction resistance (Rᵢₙᵢₜᵢₐₗ) of each test Josephson junction of the selected test group (block 903). For example, in some embodiments, the resistance measurements are performed using a 4-wire (Kelvin) resistance measurement process, as discussed above in conjunction with FIG. 7A. The calibration process selects a given combination of drive current parameters (e.g., pulse amplitude and pulse duration) to configure a controlled current to drive each test microheater in the selected test group (block 904). For example, for the given calibration iteration, the calibration process can select a pulse amplitude setting A₁ and pulse duration setting of D₁ for driving each test microheater in the selected test group with a controlled DC pulse having an amplitude A₁ and duration D₁, to cause localized thermal annealing of the test Josephson junctions in the selected test group. For each subsequent calibration iteration on remaining test groups, the calibration process can select a different combination of a pulse amplitude and pulse duration to configure a controlled DC current pulse to drive the microheaters in the given test group.

The calibration process proceeds to drive each test microheater in the selected test group with a controlled current (e.g., DC current pulse) having the selected combination of drive current parameters (e.g., pulse amplitude A₁ and pulse duration D₁) to thermally anneal the associated test Josephson junctions in the selected test group (block 905). In an exemplary embodiment, each microheater in the selected test group can be concurrently driven by respective DC current pulses having the same combination of drive current parameters (e.g., pulse amplitude A₁ and pulse duration D₁). As noted above, driving a given test microheater with the controlled DC current pulse results in localized thermal annealing of the test Josephson junction(s) in local proximity to the given text test microheater.

Next, junction resistance measurements are performed to remeasure the junction resistances of each test Josephson junction of the selected test group to determine a current junction resistance R_{current} of each test Josephson junction following localized thermal annealing of the test Josephson junctions (block 906). The resistance measurement data (e.g., Rᵢₙᵢₜᵢₐₗ and R_{current}) for each test Josephson junction of the given test group is used to determine an amount of junction resistance shift that occurs due to the localized thermal annealing of the test Josephson junction as a result of driving the associated microheater at the given combination of pulse amplitude and pulse duration, and the calibration process persistently stores the resistance shift data for the given test group (block 907). For example, in some embodiments, the amount of junction resistance shift ΔR for a given test Josephson junction is determined as: ΔR=R_{current}−Rᵢₙᵢₜᵢₐₗ (and with a “resistance shift percentage” determined as:

$$Δ R \% = \frac{Δ R}{{R}_{inital}} \times 100 \% ) .$$

The resistance measurement data (e.g., Rᵢₙᵢₜᵢₐₗ, R_{current} and computed ΔR) for each test Josephson junction at the given combination of pulse amplitude and pulse duration is stored (block 907) for subsequent access and analysis. In some embodiments, the calibration process computes an average of the measured junction resistance shift percentages ΔR % for all test Josephson junctions in the given test group, wherein the average junction resistance shift percentage ΔR_{avg} % is stored for subsequent calibration analysis.

Next, the calibration process determines whether there are one or more remaining test groups to perform trial thermal annealing operations on test Josephson junctions for other combinations of drive current parameters (e.g., pulse amplitude and pulse duration settings) (block 908). If there are one or more remaining test groups (affirmative determination in block 908), the calibration process selects a next test group (return to block 902) and repeats the calibration test (repeat blocks 903, 904, 905, 906, and 907) on the next selected test group to drive the microheaters of the next selected test group with a controlled current (e.g., DC current pulse) that is configured with a next selected unique combination of pulse amplitude and pulse duration settings. On the other hand, if there are no remaining test groups (negative determination in block 908), the trial thermal annealing operations are ended (block 909).

At the completion of the trial thermal annealing operations of FIG. 9, the acquired calibration data represents the tuning characteristics of test Josephson junctions in response to localized thermal annealing of the test Josephson junctions with different thermal profiles achieved by local resistive heating of the test microheater elements being driven with different controlled currents. In some embodiments, after completion of the trial thermal annealing operation of FIG. 9, the calibration process comprises a collection of computed ΔR data or ΔR % data, which is utilized to compute calibration tuning parameters/metrics, e.g., (i) compute tuning curves that represent tuning rates of the test Josephson junctions for the each of the different thermal profiles achieved by driving the test microheater elements with different controlled currents (ii) determine maximum tuning ranges (e.g., maximum ΔR) for the test Josephson junctions for the different thermal profiles achieved by driving the test microheater elements with different controlled currents.

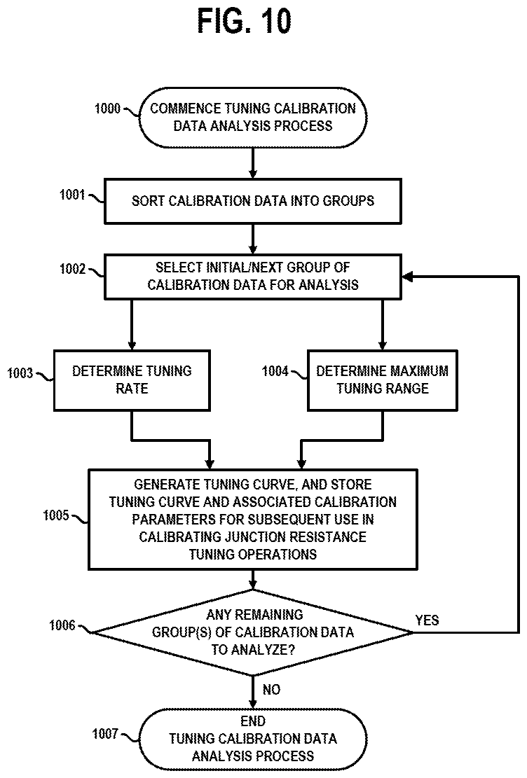

For example, FIG. 10 illustrates a flow diagram of a process for analyzing tuning calibration data to determine tuning curves and associated calibration parameters for tuning junction resistances of Josephson junctions, according to an exemplary embodiment of the disclosure. In some embodiments, FIG. 10 illustrates an exemplary process for implementing block 802 (FIG. 8) to compute tuning curves and calibration parameters for each controlled current having a unique combination of current settings (e.g., pulse amplitude and duration settings) In some embodiments, after performing the trial thermal annealing operations (FIG. 9), the control system 110 commences a tuning calibration data analysis process (block 1000) to compute tuning curves and calibration parameters based on the ΔR data.

For example, as an initial step, the calibration process accesses and sorts the calibration data acquired for each test group into groups of calibration data (block 1001). More specifically, in some embodiments, for each pulse amplitude setting of the controlled currents used to drive microheaters for the trial thermal annealing operations, the calibration process aggregates the resistance shift data of the test Josephson junctions of the test groups, which were thermally annealed by driving associated microheaters using the same pulse amplitude setting, at each of the different pulse durations. In other words, the sorting process results in multiple groups of calibration data for analysis, where each group of calibration data comprises an aggregation of the resistance shift data of test Josephson junctions obtained from localized thermal annealing of the test Josephson junctions by microheaters that were driven at the same pulse setting but with the various pulse duration settings. The sorting of the calibration data into groups of calibration data allows the calibration data to be fitted to tuning curves for each discrete pulse amplitude setting.

The calibration process selects an initial (or next) group of calibration data for analysis (block 1002). For example, the initial group of calibration data can include the resistance shift data (ΔR data) associated with groups of test Josephson junctions that were thermally annealed by driving the associated microhcaters with a controlled DC current pulse with the same pulse amplitude setting (e.g., A₁) but at the different pulse duration settings (e.g., D₁, D₂, D₃, D₄ and D₅). The group of calibration data is analyzed to determine a tuning rate coefficient for positive tuning (e.g., increase in junction resistance) for the given pulse amplitude as a function of duration (block 1003) and to determine a maximum tuning range for the positive tuning for the given pulse amplitude as a function of duration (block 1004). In some embodiments, the tuning rate coefficients and maximum tuning ranges are determined based on average junction resistance shift percentage data (ΔR_{avg}) that is computed using the measured junction resistance shift percentage data (ΔR) of the test Josephson junctions, for each of the different pulse durations at the given pulse amplitude setting. In other words, a tuning curve can be generated for a given pulse amplitude setting (A₁) as a function of pulse duration (e.g., D₁, D₂, D₃, D₄ and D₅).

For example, assume that the given group of calibration data comprises the ΔR data for each test Josephson junction that was thermally annealed by driving an associated microheater with a controlled current (DC current pulse) having the same pulse amplitude setting A₁. The measured ΔR data for each test Josephson junction that was that was thermally annealed by driving an associated microheater with a controlled current with a pulse duration of, e.g., D₁ (at the given pulse amplitude setting A₁) is utilized to determine the ΔR_{avg} for the given pulse duration of D₁ at the given pulse amplitude setting A₁. Similarly, the measured ΔR data for each test Josephson junction that was that was thermally annealed by driving an associated microheater with a controlled current (DC current pulse) with a pulse duration of D₂ (at the given pulse amplitude setting A₁) is utilized to determine the ΔR_{avg} for the given pulse duration of D₂ at the given pulse amplitude setting A₁. The same ΔR_{avg} is computed for each pulse duration setting (e.g., D₃, D₄, and D₅, etc.) at the given pulse amplitude setting A₁, and the same computations are repeated using the corresponding ΔR data for each of the test Josephson junctions that were thermally annealed by driving associated microheaters with a controlled current (DC current pulse) tuned using DC pulses with different pulse amplitude settings for the different pulse duration settings.

In some embodiments, the ΔR_{avg} parameters that are determined for the different pulse duration settings for a given pulse amplitude setting are utilized to generate a tuning curve for the given pulse amplitude setting (block 1005). For example, in some embodiments, the tuning curve for a given pulse amplitude setting is determined using a curve fitting process to fit the ΔR_{avg} data points of the different pulse duration settings for the given pulse amplitude setting to a curve using a polynomial curve fitting process (e.g., a second order (or higher order) polynomial curve fitting process). In other embodiments, the tuning curve for a given pulse amplitude setting is determined using a nonlinear regression process to fit the ΔR_{avg} % data points for the given pulse amplitude setting to a curve using, for example, a logarithmic, or inverse exponential curve. Moreover, in some embodiments, the maximum tuning range for the given pulse amplitude setting can be determined using an interpolation function (polynomial, logarithmic, or the like) where the maximum value(s) may be extracted from the extrema(s) of the tuning curve that is computed using a linear or nonlinear regression curve fitting process.

In some embodiments, the calibration process utilizes the ΔR_{avg} data points of the different pulse duration settings for the given pulse amplitude setting to generate a tuning curve for the given pulse amplitude setting and persistently stores the tuning curve and associated calibration parameters (e.g., tuning rate coefficients and maximum tuning ranges) that are derived from the ΔR_{avg} data, for subsequent use in calibrating tuning operations (block 1005). For example, in some embodiments, the tuning curve and associated calibration parameters are stored in a database of calibration data (e.g., database of tuning calibration data 115, FIG. 1).

If there are any remaining groups of calibration data to be analyzed (affirmative determination in block 1006), the calibration process selects the next group of calibration data for analysis (return to block 1002), and the process steps of blocks 1003, 1004, and 1005 are repeated for the next selected group of calibration data. The tuning calibration data analysis process terminates (block 1007) after all groups of calibration data have been analyzed. At the completion of the tuning calibration data analysis process, the tuning calibration database can have computed tuning curves associated with calibration parameters for configuring controlled currents (e.g., DC current pulses, AC current signals) for driving associated microheaters to tune the junction resistances of Josephson junctions by localized thermal annealing of the Josephson junctions.

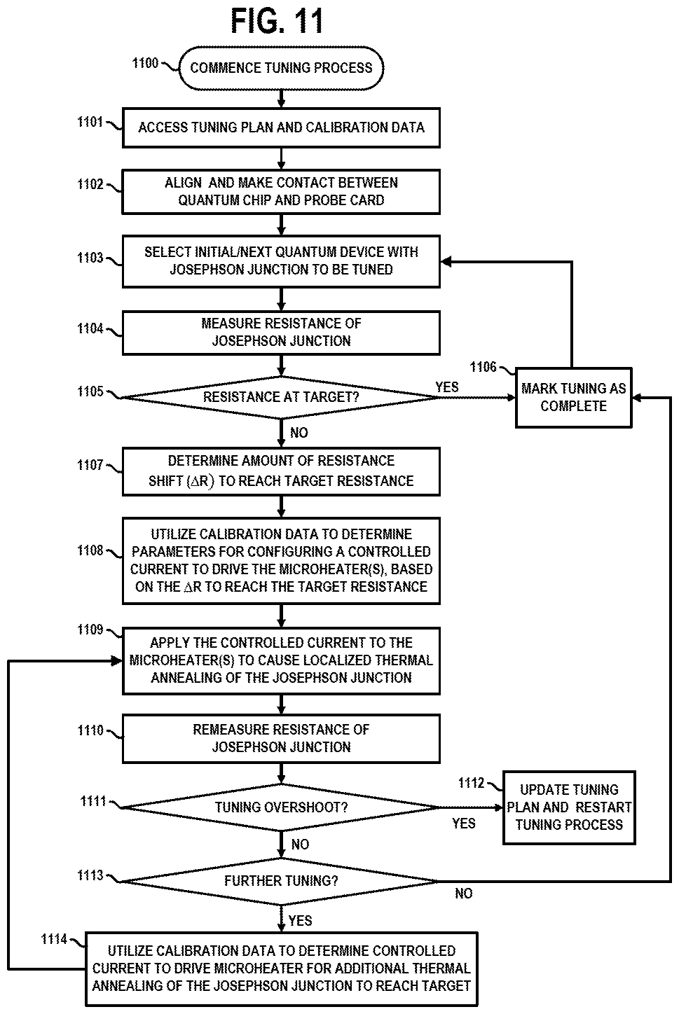

FIG. 11 illustrates a flow diagram of a method for tuning junction resistances of Josephson junctions, according to another exemplary embodiment of the disclosure. In some embodiments, FIG. 11 illustrates an automated tuning process, which can be performed using the system 100 of FIG. 1, to tune Josephson junctions to respective R_{target} values and thereby tune superconducting qubits in a qubit lattice on a quantum chip to respective target transition frequencies as specified by a frequency tuning plan. The tuning process of FIG. 11 is configured to utilize tuning calibration data to accurately determine and configure controlled currents for driving microheater elements to achieve target thermal profiles for localized thermal annealing of Josephson junctions and thereby control the amount of junction resistance shifts of the Josephson junctions.

Referring to FIG. 11, a quantum chip is placed on the X-Y-Z stage 132 of the prober unit 130, and the control system 110 commences an automated tuning process (block 1100). In an exemplary embodiment, the quantum chip comprises a plurality of superconducting qubits arranged in a given qubit lattice, wherein each superconducting qubit comprises at least one microheater to enable localized thermal annealing of an associated Josephson junction. The tuning process accesses a frequency tuning plan generated for the given qubit lattice, and tuning calibration data associated with the Josephson junctions of the superconducting qubits (block 1101). In some embodiments, the frequency tuning plan specifies respective R_{target} values for the Josephson junctions, as well as calibration parameters for determining suitable drive current parameters for configuring controlled currents for driving the on-chip microheaters to cause localized thermal annealing of associated Josephson junctions of the superconducting qubits.

The automated tuning process controls the operation of the microscope unit 120 and the prober unit 130 to align the quantum chip to a probe card (e.g., via automated pattern recognition) and to make contact between contact pads on the quantum chip and electrical probes of the probe card (e.g., vertically move the quantum chip on the X-Y-Z stage to make contact to the probe card) (block 1102). The automated tuning process then proceeds to perform a series of junction resistance measurements and thermal annealing operations to tune the Josephson junctions of the superconducting qubits to their respective target junction resistances. For illustrative purposes, the exemplary tuning process flow of FIG. 11 will be described in the context of an iterative process wherein the tuning is performed for one Josephson junction at a given time for each iteration. However, in other embodiments, the multiple Josephson junctions can be tuned concurrently in instances where the probe card has electrical probes in contact with the superconducting capacitor pads and microheater elements of a subset or all of the superconducting qubits on the quantum chip.

The tuning process proceeds to select an initial quantum device (e.g., superconducting qubit) with a target Josephson junction to be tuned (block 1103). The tuning process then proceeds to measure the initial junction resistance Rᵢₙᵢₜᵢₐₗ of the target Josephson junction (block 1104) using a 4-wire (Kelvin) probe resistance measurement technique as discussed above in conjunction with, e.g., FIG. 7A. Moreover, in some embodiments, contact resistance and contact stability checks are initially performed, prior to performing the junction resistance measurement, to ensure that the contact resistance is below a given threshold, and to ensure that the contact between the electrical probe and the contact pads of the Josephson junction and stable and not intermittent.

Next, a determination is made as to whether the initial junction resistance Rᵢₙᵢₜᵢₐₗ of the Josephson junction is at or near the specified target resistance (block 1105). For example, in some embodiments, the junction resistance of the given Josephson junction will be deemed to be at or near the target junction resistance R_{target} if the currently measured junction resistance R_{current} is within some specified resistance threshold R_{threshold} (e.g., ±0.3%) of the target junction resistance R_{target}, i.e.,

$${R}_{threshold} = \frac{\vert {R}_{target} - {R}_{current} \vert}{{R}_{target}} \leq x ( e . g . , x = 0.003 ( or 0.3 \% ) ) .$$

When the given Josephson junction has an initial junction resistance Rᵢₙᵢₜᵢₐₗ which is deemed to be at or near its target junction resistance R_{target} within the specified resistance threshold R_{threshold}, it is assumed that the corresponding superconducting qubit is properly tuned and is within a corresponding bound of precision to its respective target transition frequency.

In this regard, if the initial junction resistance Rᵢₙᵢₜᵢₐₗ of the Josephson junction is determined to be at or near the specified target resistance (affirmative determination in block 1105), the tuning of the superconducting qubit is marked as complete (block 1106), and the tuning process selects a next superconducting quantum bit with a Josephson junction to be tuned (return to block 1103). On the other hand, if the initial junction resistance Rᵢₙᵢₜᵢₐₗ of the Josephson junction is determined to not be at or near the specified target resistance (negative determination in block 1105), the tuning process will proceed to determine an amount of resistance shift, ΔR_{target}=R_{target}−Rᵢₙᵢₜᵢₐₗ, which is needed to reach the target junction resistance R_{target} (block 1107). In some embodiments, the tuning process determines

$$Δ {R}_{target} \% = \frac{Δ {R}_{target}}{{R}_{initial}} \times 100 \% .$$

Next, the tuning process utilizes the determined amount of resistance shift (e.g., ΔR_{target} or ΔR_{target} %) to determine, from the calibration data, a suitable combination of drive current parameters (e.g., pulse amplitude and pulse duration) to configure a controlled current (e.g., DC current pulse) to drive the microheater(s), which are associated with the given superconducting qubit, to achieve a target thermal profile for the localized thermal annealing of the given Josephson junction (block 1108). The tuning process then configures and applies the controlled current to the microheater(s) to generate the target thermal profile for the localized thermal annealing of the target Josephson junction to thereby shift the junction resistance of the given Josephson junction to the target junction resistance (block 1109).

After completion of the localized thermal annealing, the tuning process proceeds to remeasure the junction resistance of the given Josephson junction (block 1110) using a 4-wire (Kelvin) probe resistance measurement technique as discussed above in conjunction with, e.g., FIG. 7A. The tuning process will determine whether or not the junction resistance of the given Josephson junction has exceeded the target junction resistance resulting in an undesired tuning overshoot (block 1111). If the tuning process determines that a tuning overshoot has resulted for the given Josephson junction (affirmative determination in block 1111), the tuning process can be paused, to allow a new or updated frequency tuning plan to be generated which takes into account the tuning overshoot of the given Josephson junction (block 1112), in which case the tuning process can be restarted using the new or updated frequency tuning plan. An exemplary process for generating a new or updated frequency tuning plan will be discussed in further detail below in conjunction with FIG. 12.

On the other hand, if the tuning process determines that a tuning overshoot has not resulted for the given Josephson junction (negative determination in block 1111), the tuning process will determine if further resistance tuning is needed to reach the target junction resistance of the given Josephson junction (block 1113). For example, in some embodiments, as noted above, a determination is made as to whether the remeasured junction resistance R_{current} is at or near the target junction resistance R_{target} within some specified threshold R_{threshold} (e.g., ±0.3%) of the target junction resistance R_{target}. If the tuning process determines that no further resistance tuning is needed to reach the target junction resistance of the given Josephson junction (negative determination in block 1113), the tuning for the given Josephson junction will be marked complete (block 1106), and the tuning process selects a next superconducting qubit with an associated Josephson junction to be tuned (return to block 1105) and repeats the tuning process for the next Josephson junction.

On the other hand, if the tuning process determines that further resistance tuning is needed to reach the target junction resistance of the given Josephson junction (affirmative determination in block 1113), the tuning process will utilize the calibration data to determine another controlled current to drive the microheater to further thermally anneal the given Josephson junction to cause a further shift in the junction resistance of the given Josephson junction to the target junction resistance (block 1114). The tuning process will then proceed to apply the additional controlled current to the microheater(s) to cause further localized thermal annealing of the given Josephson junction to shift the junction resistance to the target junction resistance (return to block 1109), and the process flow (e.g., blocks 1110-1113) is repeated for the given Josephson junction.

While FIG. 11 is discussed in the context of utilizing calibration data to determine controlled DC current pulses to drive microheaters to cause localized thermal annealing of Josephson junctions, it is to be noted that the same or similar process flow can be implemented in the context of utilizing calibration data to determine tuning parameters for configuring controlled AC current pulses (e.g., frequency, peak amplitudes, duration, etc.) to drive microheaters which are configured with pickup coils (e.g., FIG. 3C) to perform localized thermal annealing of the Josephson junctions. Moreover, while exemplary junction resistance measurements can be implemented at room temperature, in other embodiments, the junction resistance measurements can be performed at low temperatures using, e.g., the thermoelectric element 133 of the X-Y-Z stage 132 (FIG. 1). For example, low temperature junction resistance measurements (e.g., in range of about −20° C. to about −60° C. enable more precise resistance measurements by, e.g., performing low noise electrical measurements by suppressing noise that is intrinsic to the Josephson junction itself, as well as reducing the contribution of substrate conductivity on the junction resistance measurement. Moreover, in some embodiments, AC junction resistance measurements can be performed (e.g., at a frequency of about 1.0 kHz or greater), wherein high-frequency resistance measurements are configured to mitigate 1/f noise, and thereby increase the precision of the junction resistance measurements.

FIG. 12 illustrates a flow diagram of a method 1200 for generating and updating a frequency tuning plan of a quantum bit array, according to an exemplary embodiment of the disclosure. In some embodiments, the method 1200 of FIG. 12 can be utilized to generate an initial frequency tuning plan for a given quantum bit array prior to commencing a tuning process. Further, as noted above, the process of FIG. 12 can be utilized to modify/update the frequency tuning plan (e.g., implement block 1112 in FIG. 11) during a tuning process, as needed, based on the progression of the tuning process to ensure that a yield rate remains acceptable. As noted above, a frequency tuning plan is generated to assist in tuning the transition frequencies of superconducting qubits in a given qubit lattice to avoid frequency collisions in the qubit lattice when performing gate operations (e.g., single gate operations, multi-gate operations (e.g., two-qubit gate entanglement operations, etc.) on a quantum chip (e.g., quantum processor).

Referring to FIG. 12, the method 1200 involves defining/determining a plurality of key constraints for a given frequency tuning plan including defining various types of frequency collisions that may occur based on a given qubit lattice architecture (block 1201), defining bounds of such collisions (block 1202), and defining tuning ranges, e.g., minimum and maximum tuning ranges (block 1203). In some embodiments, the tuning ranges are derived by analyzing the tuning calibration data obtained from the trial thermal annealing operations performed on the groups of test Josephson junctions with different thermal profiles achieved by driving on-chip microheaters with different controlled currents, such as discussed above.

The process proceeds to generate or update the frequency tuning plan (block 1204) based on, e.g., the defined collision types, the frequency collision bounds for each collision type, the maximum/minimum tuning ranges, etc. In some embodiments, the tuning plan generation process determines respective target junction resistances (R_{target}) for the Josephson junctions of the superconducting qubits to achieve frequency collision avoidance. More specifically, in some embodiments, the tuning plan generation process determines the respective target junction resistances (R_{target}) for the Josephson junctions of the superconducting qubits based on initial measured junction resistances (Rᵢₙᵢₜᵢₐₗ) of the Josephson junctions and the tuning range calibration data associated with the Josephson junctions of the qubits. The target junction resistances (R_{target}) of the respective Josephson junctions of the qubits are utilized to predict the target transition frequencies of the respective qubits.

After generating or updating the frequency tuning plan, the process performs a yield estimate process to analyze the frequency tuning plan (block 1205). In some embodiments, the yield estimate process is performed using Monte Carlo simulations to statistically determine how many frequency collisions are expected based on the given frequency tuning plan, and performing other analytical processes for gamma computations, gate error modeling, etc. The yield analysis is performed to predict and quantify collisions and zero-collision probability and gate fidelity comparing against pre-defined acceptance thresholds. In particular, in some embodiments, the yield analysis comprises performing collision analysis for nearest-neighbor and next nearest-neighbor degeneracies. In addition, a statistical analysis (e.g., Monte Carlo) is performed to identify an expected number of collisions given a frequency prediction imprecision, or set of frequency prediction imprecisions. In addition, a collision yield is computed to obtain a zero-collision probability, and a gate error analysis is performed to estimate gate fidelities (error yield).

If the results of the yield analysis are acceptable (affirmative determination in block 1206), the updated frequency tuning plan is deemed to be acceptable and the tuning process proceeds based on the updated frequency tuning (block 1207). On the other hand, if the results of the yield analysis are deemed to be unacceptable (negative determination in block 1206), the frequency tuning plan is deemed to be unacceptable given the existing tuning state of the Josephson junctions. As a result, the process proceeds to determine if alternate constraints are possible for revising the tuning plan to achieve a favorable yield analysis (block 1208). For example, in some embodiments, alternate constraints include, e.g., increasing the tuning range, changing frequency collision weights or collision bounds, etc.

If alternate constraints are possible (affirmative determination in block 1208), the method 1200 proceeds to select new constraints (block 1209), to generate a new or updated frequency tuning plan based on the new constraints (return to block 1204), and perform another yield analysis (block 1205) based on the new or updated frequency tuning plan and the existing tuning state of the Josephson junctions. On the other hand, if there exists a given circumstance in which no alternate constraints are possible for generating a new tuning plan (negative determination in block 1208), the tuning process terminates for the given quantum chip, and a new quantum chip is selected for tuning (block 1210).

It is to be appreciated that the use of on-chip microheaters to generate heat for localized thermal annealing and, thus junction resistance tuning, of Josephson junctions provides various advantages over conventional methods that perform laser annealing via laser techniques. For example, the exemplary thermal annealing techniques as discussed herein take advantage of the tremendous capability of microfabrication and lithography methods to fabricate various types and configurations of on-chip microheaters which can be disposed in local proximity to Josephson junctions and driven with controlled currents to generate Joule heating which is sufficient for localized thermal annealing of the Josephson junctions. Indeed, the ability to use on-chip microheaters to generate custom thermal profiles for thermal annealing to accurately tune the junction resistances of Josephson junctions, post fabrication, is of great importance for scaling up superconducting quantum computers. While laser tuning techniques provide an effective way to locally heat target Josephson junctions for resistance tuning, such laser tuning techniques require complicated and expensive laser optics to generate and apply laser beam illumination on target regions of a quantum chip to thermally anneal Josephson junctions. Moreover, laser tuning techniques can be slow because laser tuning requires repeated alignment and focusing operations to applying laser beams to target regions of each qubit to thermally anneal the associated Josephson junction of the qubits, one junction at a time. Moreover, laser tuning cannot be implemented once the quantum chip has been packaged.

In contrast, the use of on-chip microheaters allows localized thermal annealing by generating and applying more precise and controlled thermal profiles to heat the Josephson junctions. Indeed, the on-chip microheaters can be precisely formed and positioned in proximity to a Josephson junction by microfabrication techniques, and the amount of Joule heating applied to the Josephson junctions for localized thermal annealing can be precisely known based on, e.g., the known resistance of the resistive elements, and the magnitude of the controlled current that is applied to drive the microheaters. In this regard, the localized heating achieved using on-chip microheaters can be more precise and consistent than laser heating, since the localized heating achieved using laser tuning is subject to surface reflection of laser energy, laser beam spot placement, and focusing, etc. Moreover, the use of on-chip microheaters allows localized thermal annealing of Josephson junctions that are fabricated on substrates that are not optically absorptive (e.g., sapphire substrates).

Furthermore, the use of on-chip microheaters allows localized thermal annealing to be performed concurrently on multiple Josephson junctions of multiple qubits, which enables faster throughput in resistance tuning. Indeed, as noted above, a probe card can be designed with an array of electrical probe pins that can make contact to multiple contact pads of quantum devices and on-chip microheaters, etc., to enable junction resistance measurements to be concurrently performed on multiple Josephson junctions of multiple quantum devices (e.g., superconducting qubits), as well as concurrently drive multiple on-chip microheaters to concurrently perform multiple localized thermal annealing operations on multiple Josephson junctions of multiple quantum devices. In addition, as noted above, by including package wiring which is connected to the on-chip microheaters, additional localized thermal annealing operations can be performed, post packaging (after the quantum chip has been flip-chip bonded and packaged), by utilizing the package wiring to apply controlled current to drive the on-chip microheaters of the packaged quantum chip.

Moreover, the tuning apparatus needed to generate the controlled currents for driving the on-chip microheaters and performing junction resistance measurements is less complex than the tuning apparatus needed to implement laser tuning techniques. Indeed, since no laser unit or laser optics are required, many Josephson junctions can be locally heated, concurrently, to different temperatures, wherein the number of Josephson junctions that can thermally annealed, concurrently, is limited only by the number of conductive links that can be made to the different microheaters heaters by a probe card or otherwise.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

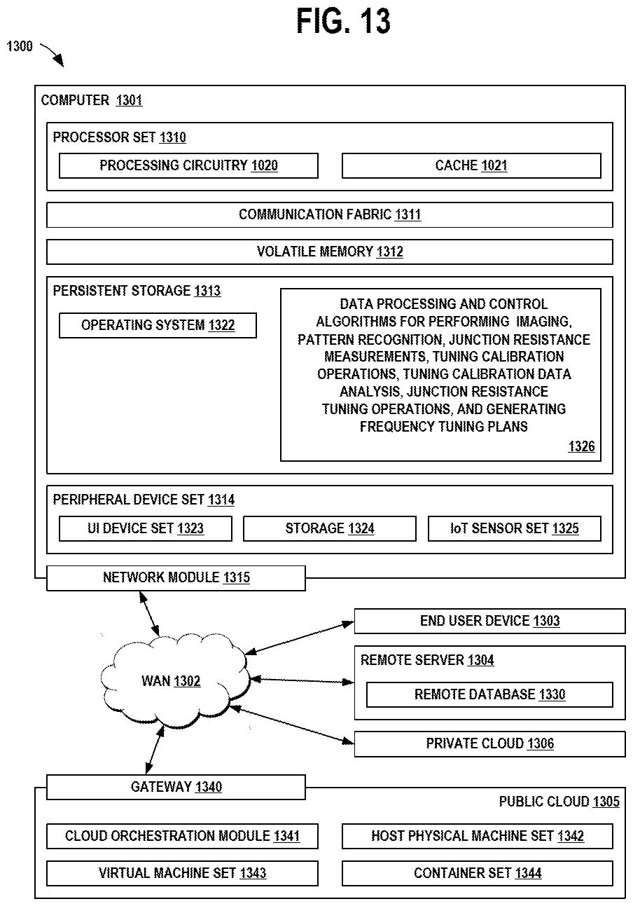

Computing environment 1300 of FIG. 13 contains an example of an environment for the execution of at least some of the computer code (block 1326) comprising data processing and control algorithms for performing various operations and function as discussed herein such as imaging, pattern recognition, junction resistance measurements, tuning calibration operations, tuning calibration data analysis, junction resistance tuning operations, generating/updating frequency tuning plans, and other computer automated control and data processing operations as discussed herein for performing the exemplary methods shown or otherwise explained in conjunction with, e.g., FIGS. 1-12. In some embodiments, as noted above, FIG. 13 schematically illustrates an exemplary architecture of a computing environment for implementing the control system 110 (FIG. 1) or portions thereof, for tuning superconducting quantum devices, according to an exemplary embodiment of the disclosure. In addition to block 1326, computing environment 1300 includes, for example, computer 1301, wide area network (WAN) 1302, end user device (EUD) 1303, remote server 1304, public cloud 1305, and private cloud 1306. In this embodiment, computer 1301 includes processor set 1310 (including processing circuitry 1320 and cache 1321), communication fabric 1311, volatile memory 1312, persistent storage 1313 (including operating system 1322 and block 1326, as identified above), peripheral device set 1314 (including user interface (UI), device set 1323, storage 1324, and Internet of Things (IOT) sensor set 1325), and network module 1315. Remote server 1304 includes remote database 1330. Public cloud 1305 includes gateway 1340, cloud orchestration module 1341, host physical machine set 1342, virtual machine set 1343, and container set 1344.

Computer 1301 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1330. As is well understood in the art of computer technology, and depending upon the technology, performance of a computer-implemented method may be distributed among multiple computers and/or between multiple locations. On the other hand, in this presentation of computing environment 1300, detailed discussion is focused on a single computer, specifically computer 1301, to keep the presentation as simple as possible. Computer 1301 may be located in a cloud, even though it is not shown in a cloud in FIG. 13. On the other hand, computer 1301 is not required to be in a cloud except to any extent as may be affirmatively indicated.

Processor set 1310 includes one, or more, computer processors of any type now known or to be developed in the future. Processing circuitry 1320 may be distributed over multiple packages, for example, multiple, coordinated integrated circuit chips. Processing circuitry 1320 may implement multiple processor threads and/or multiple processor cores. Cache 1321 is memory that is located in the processor chip package(s) and is typically used for data or code that should be available for rapid access by the threads or cores running on processor set 1310. Cache memories are typically organized into multiple levels depending upon relative proximity to the processing circuitry. Alternatively, some, or all, of the cache for the processor set may be located “off chip.” In some computing environments, processor set 1310 may be designed for working with qubits and performing quantum computing.

Computer readable program instructions are typically loaded onto computer 1301 to cause a series of operational steps to be performed by processor set 1310 of computer 1301 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1321 and the other storage media discussed below. The program instructions, and associated data, are accessed by processor set 1310 to control and direct performance of the inventive methods. In computing environment 1300, at least some of the instructions for performing the inventive methods may be stored in block 1326 in persistent storage 1313.

Communication fabric 1311 comprises the signal conduction paths that allow the various components of computer 1301 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 1312 is any type of volatile memory now known or to be developed in the future. Examples include dynamic type random access memory (RAM) or static type RAM. Typically, the volatile memory is characterized by random access, but this is not required unless affirmatively indicated. In computer 1301, the volatile memory 1312 is located in a single package and is internal to computer 1301, but, alternatively or additionally, the volatile memory may be distributed over multiple packages and/or located externally with respect to computer 1301.

Persistent storage 1313 is any form of non-volatile storage for computers that is now known or to be developed in the future. The non-volatility of this storage means that the stored data is maintained regardless of whether power is being supplied to computer 1301 and/or directly to persistent storage 1313. Persistent storage 1313 may be a read only memory (ROM), but typically at least a portion of the persistent storage allows writing of data, deletion of data and re-writing of data. Some familiar forms of persistent storage include magnetic disks and solid-state storage devices. Operating system 1322 may take several forms, such as various known proprietary operating systems or open source Portable Operating System Interface type operating systems that employ a kernel. The code included in block 1326 typically includes at least some of the computer code involved in performing the inventive methods.

Peripheral device set 1314 includes the set of peripheral devices of computer 1301. Data communication connections between the peripheral devices and the other components of computer 1301 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1323 may include components such as a display screen, speaker, microphone, wearable devices (such as goggles and smart watches), keyboard, mouse, printer, touchpad, game controllers, and haptic devices. Storage 1324 is external storage, such as an external hard drive, or insertable storage, such as an SD card. Storage 1324 may be persistent and/or volatile. In some embodiments, storage 1324 may take the form of a quantum computing storage device for storing data in the form of qubits. In embodiments where computer 1301 is required to have a large amount of storage (for example, where computer 1301 locally stores and manages a large database) then this storage may be provided by peripheral storage devices designed for storing very large amounts of data, such as a storage area network (SAN) that is shared by multiple, geographically distributed computers. IoT sensor set 1325 is made up of sensors that can be used in Internet of Things applications. For example, one sensor may be a thermometer and another sensor may be a motion detector.

Network module 1315 is the collection of computer software, hardware, and firmware that allows computer 1301 to communicate with other computers through WAN 1302. Network module 1315 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1315 are performed on the same physical hardware device. In other embodiments (for example, embodiments that utilize software-defined networking (SDN)), the control functions and the forwarding functions of network module 1315 are performed on physically separate devices, such that the control functions manage several different network hardware devices. Computer readable program instructions for performing the exemplary inventive methods can typically be downloaded to computer 1301 from an external computer or external storage device through a network adapter card or network interface included in network module 1315.

WAN 1302 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 1303 is any computer system that is used and controlled by an end user (for example, a customer of an enterprise that operates computer 1301), and may take any of the forms discussed above in connection with computer 1301. EUD 1303 typically receives helpful and useful data from the operations of computer 1301. For example, in a hypothetical case where computer 1301 is designed to provide a recommendation to an end user, this recommendation would typically be communicated from network module 1315 of computer 1301 through WAN 1302 to EUD 1303. In this way, EUD 1303 can display, or otherwise present, the recommendation to an end user. In some embodiments, EUD 1303 may be a client device, such as thin client, heavy client, mainframe computer, desktop computer and so on.

Remote server 1304 is any computer system that serves at least some data and/or functionality to computer 1301. Remote server 1304 may be controlled and used by the same entity that operates computer 1301. Remote server 1304 represents the machine(s) that collect and store helpful and useful data for use by other computers, such as computer 1301. For example, in a hypothetical case where computer 1301 is designed and programmed to provide a recommendation based on historical data, then this historical data may be provided to computer 1301 from remote database 1330 of remote server 1304.

Public cloud 1305 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1305 is performed by the computer hardware and/or software of cloud orchestration module 1341. The computing resources provided by public cloud 1305 are typically implemented by virtual computing environments that run on various computers making up the computers of host physical machine set 1342, which is the universe of physical computers in and/or available to public cloud 1305. The virtual computing environments (VCEs) typically take the form of virtual machines from virtual machine set 1343 and/or containers from container set 1344. It is understood that these VCEs may be stored as images and may be transferred among and between the various physical machine hosts, either as images or after instantiation of the VCE. Cloud orchestration module 1341 manages the transfer and storage of images, deploys new instantiations of VCEs and manages active instantiations of VCE deployments. Gateway 1340 is the collection of computer software, hardware, and firmware that allows public cloud 1305 to communicate through WAN 1302.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 1306 is similar to public cloud 1305, except that the computing resources are only available for use by a single enterprise. While private cloud 1306 is depicted as being in communication with WAN 1302, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1305 and private cloud 1306 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and to enable others of ordinary skill in the art to understand the embodiments disclosed herein.

What is claimed is:

1. A device, comprising:
a substrate;
a quantum device comprising a superconducting tunnel junction device disposed on the substrate; and
at least one heater element disposed on the substrate and configured to generate heat through resistive heating in response to a current applied to the at least one heater element, to heat a region of the substrate on which the superconducting tunnel junction device is disposed to thermally anneal the superconducting tunnel junction device.

2. The device of claim 1, wherein:
the at least one heater element comprises at least one contact pad and a resistive element connected to the at least one contact pad; and
the at least one heater element is disposed within a patterned void of a metallization feature on a surface of the substrate.

3. The device of claim 2, wherein the resistive element is serially connected to and between the at least one contact pad and the metallization feature.

4. The device of claim 2, wherein:
the at least one contact pad comprises a first contact pad and a second contact pad; and
the resistive element is serially connected to and between the first contact pad and the second contact pad.

5. The device of claim 2, wherein the metallization feature comprises superconducting pad of the quantum device.

6. The device of claim 2, wherein the metallization feature comprises a ground plane disposed on a surface of the substrate.

7. The device of claim 2, wherein the resistive element comprises a patterned metal trace.

8. The device of claim 2, wherein the resistive element comprises a doped region of the substrate.

9. The device of claim 1, wherein the quantum device and the at least one heater element are disposed on a same side of the substrate.

10. The device of claim 1, wherein the quantum device is disposed on a first side of the substrate, and the at least one heater element is disposed on a second side of the substrate and aligned to the superconducting tunnel junction device on the first side the substrate.

11. The device of claim 1, wherein:
the at least one heater element comprises an inductive pickup coil and a resistive element connected to the inductive pickup coil; and
the at least one heater element is disposed within a patterned void of a metallization feature on a surface of the substrate.

12. The device of claim 1, wherein the quantum device comprises a quantum bit, and the superconducting tunnel junction device is a Josephson junction of the quantum bit.

13. The device of claim 1, further comprising a wiring layer which comprises wiring that is electrically connected to the at least one heater element and configured to drive the at least one heater element with an external current applied on the wiring connected to the at least one heater element.

14. A device, comprising:
a substrate;
a plurality of quantum bits disposed on the substrate, each quantum bit comprising a Josephson junction; and
a plurality of heater elements disposed on the substrate;
wherein each heater element is disposed in proximity to a respective quantum bit of the plurality of quantum bits, and configured to generate heat through resistive heating in response to a current applied to the heater element, to heat a region of the substrate on which the Josephson junction of the respective quantum bit is disposed to thermally anneal the Josephson junction of the respective quantum bit.

15. The device of claim 14, wherein:
at least one heater element comprises at least one contact pad and a resistive element connected to the at least one contact pad; and
the at least one heater element is disposed within a patterned void of a metallization feature on a surface of the substrate.

16. The device of claim 15, wherein the metallization feature comprises superconducting capacitor pad of a respective quantum bit.

17. The device of claim 15, wherein the metallization feature comprises a ground plane disposed on a surface of the substrate.

18. The device of claim 15, wherein the resistive element is serially connected to and between the at least one contact pad and the metallization feature.

19. The device of claim 15 wherein:
the at least one contact pad comprises a first contact pad and a second contact pad; and
the resistive element is serially connected to and between the first contact pad and the second contact pad.

20. The device of claim 15, wherein the resistive element comprises one of a patterned metal trace and a doped region of the substrate.

21. A method, comprising:
contacting electrical probes to a heater element disposed on a substrate; and
applying a controlled current to the heater element through the electrical probes to cause the heater element to heat a portion of the substrate through resistive heating and thermally anneal a Josephson junction of a quantum bit, which is disposed in contact with the heated portion of the substrate.

22. The method of claim 21, wherein the controlled current comprises one of a direct current (DC) current pulse and alternating current (AC) current pulse.

23. A method, comprising:
measuring a resistance of a Josephson junction of a quantum bit that is disposed on a substrate; and
applying a controlled current to a heater element, which is disposed on the substrate in proximity to the Josephson junction of the quantum bit, to cause the heater element to generate heat through resistive heating and thereby heat a region of the substrate on which the Josephson junction is disposed to shift a resistance of the Josephson junction from the measured resistance to a target resistance.

24. The method of claim 23, wherein applying the current to the heater element comprises:
determining a difference between the measured resistance of the Josephson junction and the target resistance of the Josephson junction; and
utilizing calibration data to determine parameters for configuring the controlled current based at least in part on the determined difference between the measured resistance and the target resistance of the Josephson junction.

25. A system, comprising:
a prober apparatus; and
a control system operatively coupled to the prober apparatus;
wherein the control system is configured to control the prober apparatus to perform a tuning process to tune a transition frequency of at least one quantum bit of a quantum bit array on a quantum chip, wherein in performing the tuning process, the control system is configured to utilize the prober apparatus to:
measure a resistance of a Josephson junction of the at least one quantum bit;
apply a controlled current to an on-chip heater element, which is disposed in proximity to the Josephson junction of the at least one quantum bit, to cause the on-chip heater element to generate heat through resistive heating and thereby heat a region of the quantum chip on which the Josephson junction is disposed to shift a resistance of the Josephson junction from the measured resistance to a target resistance.
